(19) United States
(12) Patent Application Publication
(10) Pub. No.: US 2023/0317161 A1
(43) Pub. Date: Oct. 5, 2023

(54) MATRIX MULTIPLICATION WITH RESISTIVE MEMORY CIRCUIT HAVING GOOD SUBSTRATE DENSITY

(71) Applicant: Crossbar, Inc., Santa Clara, CA (US)

(72) Inventor: Hagop Nazarian, San Jose, CA (US)

(21) Appl. No.: 17/710,851

(22) Filed: Mar. 31, 2022

(51) Int. Cl. G11C 13/00

(52) U.S. Cl. CPC G11C 13/0069; G11C 13/0028; G11C 13/0026; G11C 13/0038; G11C 13/004; G11C 13/003; G11C 2213/79

(57) ABSTRACT

Configurable and reconfigurable solid state electronic devices for performing matrix multiplication are provided. The solid state electronic devices at least in part utilize a resistive non-volatile memory circuit for storing data states of a data matrix. In various embodiments, a circuit is provided to facilitate analog current-mediated matrix multiplication. In some aspects of these embodiments, a circuit is disclosed providing current multiplication modeling multi-order bit values through control of transistor gate voltage, significantly reducing silicon space of multi-transistor models for multiplying current.

### INCORPORATION BY REFERENCE

U.S. patent application Ser. No. 16/144,765 filed Sep. 27, 2018 (now U.S. Pat. No. 11,127,460 B2) and titled “RESISTIVE RANDOM ACCESS MEMORY MATRIX MULTIPLICATION STRUCTURES AND METHODS”, and U.S. Provisional Patent Application No. 62/566,001 filed Sep. 29, 2017 and titled “LOGIC, COMPUTING AND MANAGEMENT APPLICATIONS FOR RESISTIVE MEMORY DEVICES”, are hereby incorporated by reference herein in their respective entireties and for all purposes.

### TECHNICAL FIELD

This disclosure generally relates to resistive random access memory and more specifically to matrix multiplication circuits utilizing resistive switching memory.

### BACKGROUND

Resistive-switching memory represents a recent innovation within the field of integrated circuit technology. While much of resistive-switching memory technology is in the development stage, various technological concepts for resistive-switching memory have been demonstrated by the inventor and are in one or more stages of verification to prove or disprove associated theories or techniques. The inventor believes that resistive-switching memory technology shows compelling evidence to hold substantial advantages over competing technologies in the semiconductor electronics industry.

Over time, advancement in technology has provided an increase in a number of semiconductor devices, such as transistors, that can be fabricated on a given geometric area of a semiconductor chip. An implication of increasing the number of semiconductor devices is increasing memory capacity and processing power for the semiconductor chip and associated electronic devices.

Models for resistive-switching memory proposed by the inventor utilize two-terminal structures. Two-terminal memory technology is contrasted, for instance, with gate-controlled transistors in which conductivity between two terminals is mediated by a third terminal, called a gate terminal. Two-terminal memory devices can differ from three terminal devices in function as well as structure. For instance, some two-terminal memory devices can be constructed between a pair of conductive contacts, as opposed to having a third terminal that is adjacent to a set of conductive terminals. Rather than being operable through a stimulus applied to the third terminal, two-terminal memory devices can be controlled by applying a stimulus at one or both of the pair of conductive contacts. Two-terminal memory technology can include phase-change memory, magneto-resistive memory, conductive-bridging memory, as well as others.

While much of resistive memory technology is in the development stage, various technological concepts for resistive memory have been demonstrated by the assignee of the present invention and are in one or more stages of verification to prove or disprove associated theory(ies). Even so, resistive memory technology promises to hold substantial advantages over competing technologies in the semiconductor electronics industry.

As models of resistive memory technology are tested and results obtained, the results are speculatively extrapolated to memory devices in which resistive memory replaces a conventional memory. For instance, the assignee of the present invention has conducted research related to software models of memory arrays comprising resistive memory instead of complementary metal-oxide semiconductor (CMOS) NAND or NOR memory. Software projections suggest that two-terminal memory arrays can provide significant benefits for electronic devices, including reduced power consumption, higher memory density, advanced technology nodes, or improved performance, among others.

Drawing from existing research, applications where two-terminal memory can provide real-world benefits for electronic devices are disclosed herein.

### SUMMARY

The following presents a simplified summary of the specification in order to provide a basic understanding of some aspects of the specification. This summary is not an extensive overview of the specification. It is intended to neither identify key or critical elements of the specification nor delineate the scope of any particular embodiments of the specification, or any scope of the claims. Its purpose is to present some concepts of the specification in a simplified form as a prelude to the more detailed description that is presented in this disclosure.

According to embodiments of the present disclosure, solid state matrix multiplication is provided at least in part utilizing a resistive non-volatile memory circuit for storing data states of a data matrix. In various embodiments, a circuit is provided to facilitate analog current-mediated matrix multiplication. In some aspects of these embodiments, a circuit is disclosed providing current multiplication through control of transistor gate voltage, significantly reducing silicon space of multi-transistor models for multiplying current.

In an embodiment, disclosed is a solid state logic system. The solid state logic system can comprise a plurality of bit lines comprising a bit line, and a plurality of wordlines comprising a first wordline and a second wordline. Additionally, the solid state logic system can comprise a first memory circuit at an intersection of the bit line and the first wordline and can comprise a first non-volatile resistive switching cell. Furthermore, the solid state logic system can comprise a second memory circuit at a second intersection of the bit line and the second wordline and can comprise a second non-volatile resistive switching cell, wherein respective data values corresponding to a first data matrix are stored at the first non-volatile resistive switching cell and at the second non-volatile resistive switching cell, and wherein a second data matrix is received onto the plurality of wordlines and is provided to the solid state logic system as a system input. In one or more aspects of the disclosed embodiments, in response to receiving the second data matrix on the plurality of wordlines and storing of the first data matrix at the resistive switching memory cells, the non-volatile memory logic system generates an output on the plurality of bit lines. In still further aspects, the first memory circuit can further comprise a transistor device having a channel region and a control gate, and the transistor device can be directly or indirectly responsive to a value stored at the first non-volatile resistive switching cell, and can be associated with a plurality of conductance values respectively corresponding to different voltage magnitudes applied to the control gate.

Also disclosed is a method, which can comprise programming a first resistive memory circuit with a first data value of a first data matrix, and can comprise programming a second resistive memory circuit with a second data value of the first data matrix. Further, the method can comprise inputting data values of a second data matrix onto a plurality of wordlines coupled to the first resistive memory circuit or to the second resistive memory circuit and can comprise sensing a bit line connected to the first resistive memory circuit and to the second resistive memory circuit for a response of a solid state logic device to the inputting of the data values of the second data matrix onto the plurality of wordlines. In one or more aspects of the disclosed embodiments, the solid state logic device can comprise the first resistive memory circuit, the second resistive memory circuit, the bit line and the plurality of wordlines. Still further, the method can comprise generating an output representing the response of the solid state logic device in response to sensing the bit line. In aspects of disclosed embodiments, the first resistive memory circuit can comprise a non-volatile two-terminal resistive switching memory cell for storing the first data value and a transistor device directly or indirectly responsive to the first data value stored at the non-volatile two-terminal resistive switching memory cell for generating a portion of the output on the bit line.

The following description and the drawings set forth certain illustrative aspects of the specification. These aspects are indicative, however, of but a few of the various ways in which the principles of the specification can be employed. Other advantages and novel features of the specification will become apparent from the following detailed description of the specification when considered in conjunction with the drawings.

### BRIEF DESCRIPTION OF THE DRAWINGS

Numerous aspects, embodiments, objects, and advantages of the present invention will be apparent upon consideration of the following detailed description, taken in conjunction with the accompanying drawings, in which like reference characters refer to like parts throughout. In this specification, numerous specific details are set forth in order to provide a thorough understanding of this disclosure. It should be understood, however, that certain aspects of the subject disclosure can be practiced without these specific details, or with other methods, components, materials, etc. In other instances, well-known structures and devices are shown in block diagram form to facilitate describing the subject disclosure;

FIG. 1 depicts a diagram of an example matrix multiplication utilizing solid state logic incorporating resistive memory, in an embodiment;

FIG. 2 illustrates a diagram of an example multi-bit matrix multiplication in further embodiments of the present disclosure;

FIGS. 3A, 3B and 3C illustrate example logic circuits for implementing matrix multiplication in an electric device, according to further embodiments;

FIG. 4 illustrates an example logic circuit utilized in a matrix multiplication according to one or more embodiments;

FIG. 5 depicts a second example logic circuit utilized for the matrix multiplication achieving improved silicon density, in further embodiments;

FIG. 5A provides comparative characteristics of the example logic circuit and the second example logic circuit;

FIG. 6 illustrates a diagram of an example logic circuit utilized in a matrix multiplication according to alternative or additional embodiments;

FIG. 7 depicts an example multi-bit matrix multiplication utilizing solid state logic according to still other embodiments of the present disclosure;

FIG. 8 illustrates an example current-voltage response of a transistor device according to the second logic circuit of FIG. 5;

FIG. 9 illustrates an example method of operating a disclosed electronic device for implementing matrix multiplication according to additional embodiments;

FIG. 10 illustrates a block diagram of an example electronic operating environment in accordance with certain embodiments of the subject disclosure;

FIG. 11 depicts a block diagram of an example computing environment in accordance with certain embodiments of the subject disclosure.

### DETAILED DESCRIPTION

### Introduction

Embodiments of the present disclosure provide an electric device having an array of resistive memory circuits for implementing matrix multiplication with solid state logic. The resistive memory circuits can comprise two-terminal, non-volatile resistive switching memory cells for storing data values of a first data matrix. Input of a second data matrix to the resistive memory circuits results in an output representing a product of a matrix multiplication of the first data matrix and the second data matrix. In various embodiments, resistive memory circuits are disclosed that effectively reduce a substrate area consumed by the resistive memory circuits, increasing device density on a substrate.

As the name implies, a two-terminal resistive switching device has two terminals or electrodes. Herein, the terms “electrode” and “terminal” are used interchangeably; moreover, a two-terminal resistive switching device includes a non-volatile two-terminal memory device as well as a volatile two-terminal switching device. Generally, a first electrode of a two-terminal resistive switching device is referred to as a “top electrode” (TE) and a second electrode of the two-terminal resistive switching device is referred to as a “bottom electrode” (BE), although it is understood that electrodes of two-terminal resistive switching devices can be according to any suitable arrangement, including a horizontal arrangement in which components of a memory cell are (substantially) side-by-side rather than overlying one another. Between the TE and BE of a two-terminal resistive switching device is typically an interface layer sometimes referred to as a switching layer, a resistive switching medium (RSM) or a resistive switching layer (RSL); such devices are not limited to these layers, however, as one or more barrier layer(s), adhesion layer(s), ion conduction layer(s), seed layer(s), particle source layer(s) or the like - as disclosed herein, disclosed within a publication incorporated by reference herein, as generally understood and utilized in the art or reasonably conveyed to one of ordinary skill in the art by way of the context provided herein and its addition to the general understanding in the art or the incorporated publications—may be included between or adjacent one or more of the TE, the BE or the interface layer consistent with suitable operation of such device.

One example of a resistive switching memory is a filamentary resistive memory cell. Composition of memory cells, generally speaking, can vary per device with different components, materials or deposition processes selected to achieve desired characteristics (e.g., stoichiometry/non-stoichiometry, volatility/non-volatility, on/off current ratio, switching time, read time, memory durability, program/erase cycle, and so on). One example of a filamentary-based device can comprise: a conductive layer, e.g., metal, metal-alloy, metal-nitride, (e.g., comprising TiN, TaN, TiW, or other suitable metal compounds), an optional interface layer (e.g., doped p-type (or n-type) silicon (Si) bearing layer: e.g., a p-type or n-type Si bearing layer, p-type or n-type polysilicon, p-type or n-type polycrystalline SiGe, etc.), a resistive switching layer (RSL) and an active metal-containing layer capable of being ionized. Under suitable conditions, the active metal-containing layer can provide filament-forming ions to the RSL. In such embodiments, a conductive filament (e.g., formed by the ions) can facilitate electrical conductivity through at least a subset of the RSL, and a resistance of the filament-based device can be determined, as one example, by a tunneling resistance between the filament and the conductive layer. A memory cell having such characteristics may be described as a filamentary-based device (or filamentary resistive switching device, and so forth).

A RSL (which can also be referred to in the art as a resistive switching media (RSM)) can comprise, e.g., an undoped amorphous Si-containing layer, a semiconductor layer having intrinsic characteristics, a stoichiometric or non-stoichiometric silicon nitride (e.g., SiN, Si₃N₄, SiNₓ, etc.), a Si sub-oxide (e.g., SiOₓ wherein x has a value between 0.1 and 2), a Si sub-nitride, a metal oxide, a metal nitride, a non-stoichiometric silicon compound, and so forth. Other examples of materials suitable for the RSL could include Si_{X}Ge_{y}O_{z} (where x, y and z are respective suitable positive numbers), a silicon oxide (e.g., SiON, where N is a suitable positive number), a silicon oxynitride, an undoped amorphous Si (a-Si), amorphous SiGe (a-SiGe), TaO_{B} (where B is a suitable positive number), HfO_{C} (where C is a suitable positive number), TiO_{D} (where D is a suitable number), AWE (where E is a suitable positive number) and so forth, a nitride (e.g., AlN, SiN), or a suitable combination thereof.

In some embodiments, a RSL employed as part of a non-volatile memory device (non-volatile RSL) can include a relatively large number (e.g., compared to a volatile selector device) of material voids or defects to trap neutral metal particles (e.g., at low voltage) within the RSL. The large number of voids or defects can facilitate formation of a thick, stable structure of the neutral metal particles. In such a structure, these trapped particles can maintain the non-volatile memory device in a low resistance state in the absence of an external stimulus (e.g., electrical power), thereby achieving non-volatile operation. In other embodiments, a RSL employed for a volatile selector device (volatile RSL) can have very few material voids or defects for trapping particles. Because of the few particle-trapping voids/defects, a conductive filament formed in such an RSL can be quite thin (e.g., one to a few particles wide depending on field strength, particle material or RSL material, or a suitable combination of the foregoing), and unstable absent a suitably high external stimulus (e.g., a non-zero electric field, voltage, current, joule heating, or a suitable combination thereof). Moreover, the particles can be selected to have high surface energy, and good diffusivity within the RSL. This leads to a conductive filament that can form rapidly in response to a suitable stimulus, but also deform quite readily, e.g., in response to the external stimulus dropping below a deformation magnitude (which can be lower than a formation magnitude of the external stimulus associated with forming the volatile conductive filament, e.g., in response to a current flowing through the selector device; see U.S. Pat. No. 9,633,724 B2 hereby incorporated by reference herein in its entirety and for all purposes). Note that a volatile RSL and conductive filament for the selector device can have different electrical characteristics than a conductive filament and non-volatile RSL for the non-volatile memory device. For instance, the selector device RSL can have higher material electrical resistance, and can have higher on/off current ratio, among others.

An active metal-containing layer for a filamentary-based memory cell can include, among others: silver (Ag), gold (Au), titanium (Ti), titanium-nitride (TiN) or other suitable compounds of titanium, nickel (Ni), copper (Cu), aluminum (Al), chromium (Cr), tantalum (Ta), iron (Fe), manganese (Mn), tungsten (W), vanadium (V), cobalt (Co), platinum (Pt), hafnium (Hf), and palladium (Pd). Other suitable conductive materials, as well as stoichiometric or non-stoichiometric: compounds, nitrides, oxides, alloys, mixtures or combinations of the foregoing or similar materials can be employed for the active metal-containing layer in some aspects of the subject disclosure. Further, a non-stoichiometric compound, alloy or mixture, such as a non-stoichiometric metal oxide/metal-oxygen or metal nitride/metal nitrogen (e.g., AlOₓ, AlNₓ, CuOₓ, CuNₓ, AgOₓ, AgNₓ, and so forth, where x is a suitable positive number or range of numbers, such as: 0<x<2, 0<x<3, 0<x<4 or other number/range of numbers depending on metal compound, which can have differing values for differing ones of the non-stoichiometric compounds) or other suitable metal compound can be employed for the active metal-containing layer, in at least one embodiment.

In one or more embodiments, a disclosed filamentary resistive switching device can include an active metal layer comprising a metal-nitrogen selected from the group consisting of: TiNₓ, TaNₓ, AlNₓ, CuNₓ, WNₓ and AgNₓ, where x is a positive number (or range of numbers) that can vary per metal-nitrogen material (including a compound, mixture or alloy of metal and nitrogen, or suitable combination thereof). In a further embodiment(s), the active metal layer can comprise a metal-oxygen selected from the group consisting of: TiOₓ, TaOₓ, AlOₓ, CuOₓ, WOₓ and AgOₓ where x is a positive number (or range of numbers) that can likewise vary per metal-oxygen material. In yet another embodiment(s), the active metal layer can comprise a metal oxygen-nitrogen selected from the group consisting of: TiOₐN_{b}, AlOₐN_{b}, CuOₐN_{b}, WOₐN_{b} and AgOₐN_{b}, where a and b are suitable positive numbers/ranges of numbers. The disclosed filamentary resistive switching device can further comprise a switching layer comprising a switching material selected from the group consisting of: SiO_{y}, AlN_{y}, TiO_{y}, TaO_{y}, AlO_{y}, CuO_{y}, TiNₓ, TiN_{y}, TaNₓ, TaN_{y}, SiOₓ, SiN_{y}, AlNₓ, CuNₓ, CuN_{y}, AgNₓ, AgN_{y}, TiOₓ, TaOₓ, AlOₓ, CuOₓ, AgOₓ, and AgO_{y}, where x and y are positive numbers (or ranges), and y is larger than x.

Various combinations of the above are envisioned and contemplated within the scope of embodiments of the present invention.

In one example, a disclosed filamentary resistive switching device comprises a particle donor layer (e.g., the active metal-containing layer) comprising a stoichiometric or non-stoichiometric metal compound (or mixture) and a resistive switching layer. In one alternative embodiment of this example, the particle donor layer comprises a metal-nitrogen: MNₓ, e.g., AgNₓ, TiNₓ, AlNₓ, etc., and the resistive switching layer comprises a metal-nitrogen: MN_{y}, e.g., AgO_{y}, TiO_{y}, AlO_{y}, and so forth, where y and x are positive numbers (or ranges), and in some cases y is larger than x. In an alternative embodiment of this example, the particle donor layer comprises a metal-oxygen: MOₓ, e.g., AgOₓ, TiOₓ, AlOₓ, and so on, and the resistive switching layer comprises a metal-oxygen: MO_{y}, e.g., AgO_{y}, TiO_{y}, AlO_{y}, or the like, where y and x are positive numbers (or ranges), and in some cases y is larger than x. In yet another alternative, the metal compound of the particle donor layer is a MNₓ (e.g., AgNₓ, TiNₓ, AlNₓ, etc.), and the resistive switching layer is selected from a group consisting of MO_{y} (e.g., AgO_{y}, TiO_{y}, AlO_{y}, etc.) and SiO_{y}, where x and y are typically non-stoichiometric values, or vice versa in a still further embodiment.

As utilized herein, variables x, y, a, b, and so forth representative of values or ratios of one element with respect to another (or others) in a compound or mixture can have different values (or ranges) suitable for respective compounds/mixtures, and are not intended to denote a same or similar value or ratio among the compounds. Mixtures can refer to non-stoichiometric materials with free elements therein—such as metal-rich nitride or oxide (metal-oxide/nitride with free metal atoms), metal-poor nitride or oxide (metal-oxide/nitride with free oxygen/nitrogen atoms)—as well as other combinations of elements that do not form traditional stoichiometric compounds as understood in the art. Some details pertaining to embodiments of the subject disclosure can be found in the following U.S. patent applications that are licensed to the assignee of the present application for patent: application Ser. No. 11/875,541 filed Oct. 19, 2007 and application Ser. No. 12/575,921 filed Oct. 8, 2009; each of the foregoing patent applications are hereby incorporated by reference herein in their respective entireties and for all purposes in addition to those incorporated by reference elsewhere herein.

As mentioned above, applying a program voltage (also referred to as a “program pulse”) to one of the electrodes of the two-terminal memory can cause a conductive filament to form in an interface layer (e.g., a RSL). By convention and as generally described herein, the TE receives the program pulse and the BE is grounded (or held at lower voltage or opposite polarity compared to the program pulse), but such is not intended to be limiting for all embodiments. Conversely, applying an “erase pulse” to one of the electrodes (generally a pulse of opposite polarity as the program pulse or to the opposite electrode as the program pulse) can break continuity of the filament, e.g., by driving the metal particles or other material that forms the filament back toward the active metal source. Properties of this conductive filament as well as its presence or absence affect the electrical characteristics of the two-terminal memory cell such as, for example, lowering the resistance and/or increasing conductance across the two terminals when the conductive filament is present as opposed to when not present.

Following program or erase pulses, a read pulse can be asserted. This read pulse is typically lower in magnitude relative to program or erase pulses and typically insufficient to affect the conductive filament and/or change the state of the two-terminal memory cell. By applying a read pulse to one of the electrodes of the two-terminal memory, a measured current (e.g., Ion) can be indicative of the conductive state of the two-terminal memory cell. For example, when the conductive filament has been formed (e.g., in response to application of a program pulse), the conductance of the cell is greater than otherwise and the measured current (e.g., Ion) reading in response to the read pulse will be greater. On the other hand, when the conductive filament is removed (e.g., in response to application of an erase pulse), the resistance of the cell is high because the interface layer has a relatively high electrical resistance, so the conductance of the cell is lower and the measured current (e.g., I_{off}) reading in response to the read pulse will be lower. By convention, when the conductive filament is formed, the memory cell is said to be in the “on-state” with a high conductance. When the conductive filament is not extant, the memory cell is said to be in the “off-state.” A memory cell being in the on-state or the off-state can be logically mapped to binary values such as, e.g., “1” and “0.” It is understood that conventions used herein associated with the state of the cell or the associated logical binary mapping are not intended to be limiting, as other conventions, including an opposite convention can be employed in connection with the disclosed subject matter. Techniques detailed herein are described and illustrated in connection with single-level cell (SLC) memory, but it is understood that the disclosed techniques can also be utilized for multi-level cell (MLC) memory in which a single memory cell can retain a set of measurably distinct states that represent multiple bits of information.

By mapping digital information to non-volatile resistance states of a two-terminal memory cell, digital information can be stored at such device. An electronic device containing many of these two-terminal memory cells can likewise store significant quantities of data. High density arrays are configured to contain as many memory cells as possible for a given area of chip space, thereby maximizing data storage capacity of a memory chip, or system-on-chip device.

### Example Resistive Switching Memory Matrix Multiplication Circuits

Various aspects or features of this disclosure are described with reference to the drawings, wherein like reference numerals are used to refer to like elements throughout. In this specification, numerous specific details are set forth in order to provide a thorough understanding of this disclosure. It should be understood, however, that certain aspects of disclosure can be practiced without these specific details, or with other methods, components, materials, etc. In other instances, well-known structures and devices are shown in block diagram form to facilitate describing the subject disclosure.

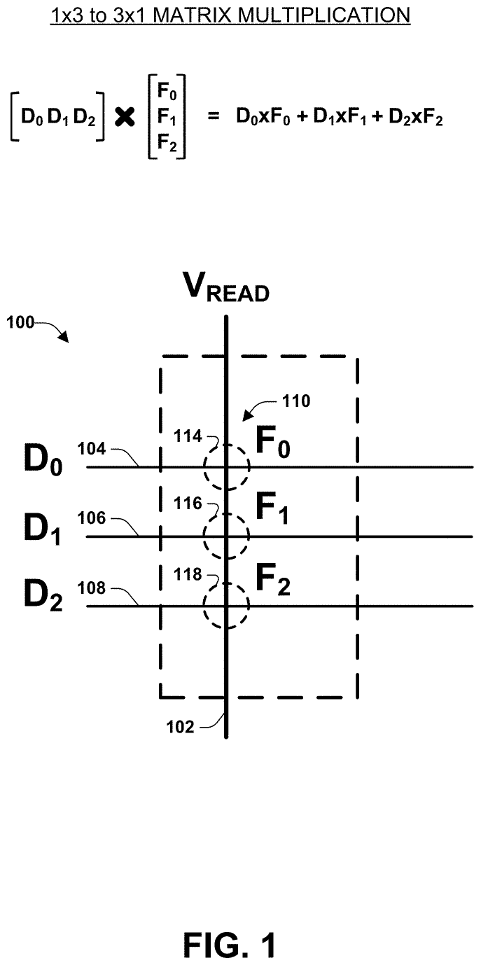

Referring initially to FIG. 1, there is illustrated an example circuit 100 for implementing a matrix multiplication utilizing solid state logic, according to various disclosed embodiments. The matrix multiplication implemented by circuit 100 is a 1×3 matrix D (including D values: D₀, D₁ and D₂) multiplied by a 3×1 matrix F (including F values: F₀, F₁ and F₂) producing a matrix product (D₀×F₀+F+D₂×F₂). By convention, the D matrix is referred to as an input matrix or a data matrix and the F matrix as a filter matrix, though other suitable terminology can be employed instead. In addition, one of ordinary skill in the art would recognize that other suitable sized matrices, having single-bit or multi-bit values, can be implemented utilizing the disclosed circuits as examples. Such embodiments and others known in the art of reasonably conveyed to one of ordinary skill in the art by way of the context provided herein are considered within the scope of the present disclosure.

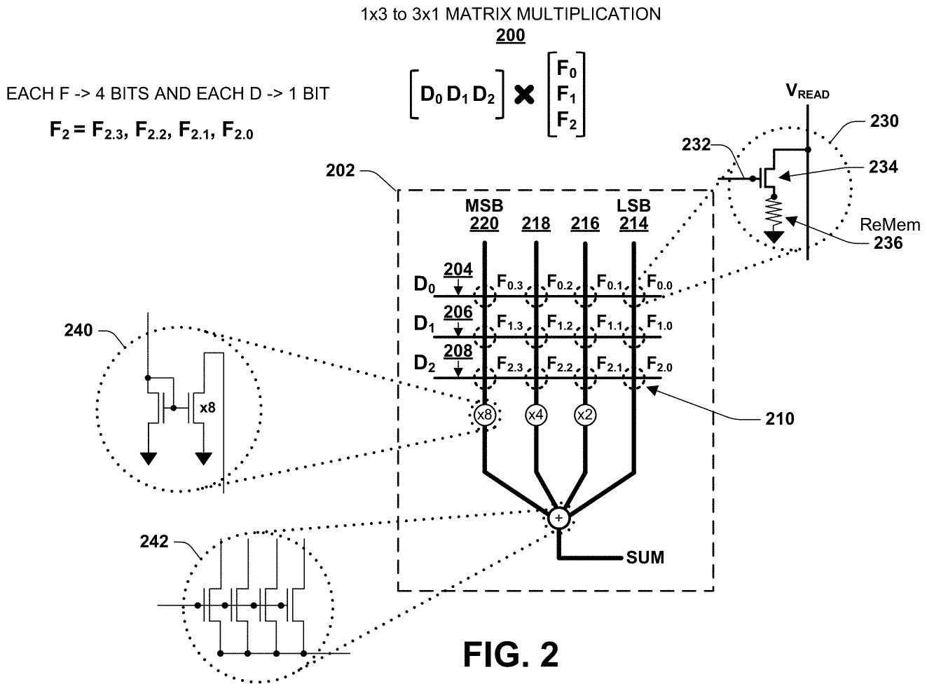

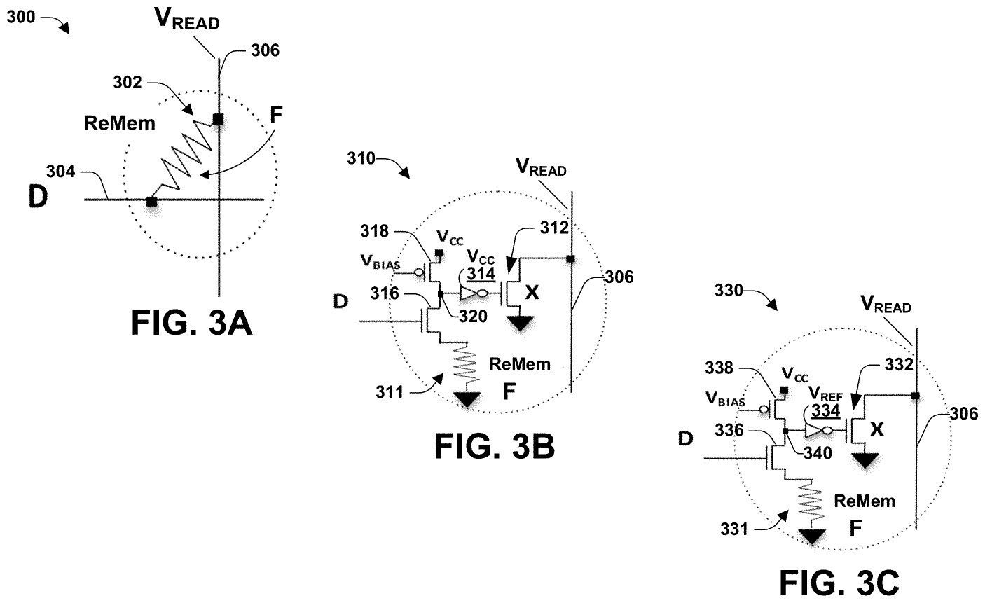

Circuit 100 includes a bit line 102 intersecting a plurality of wordlines, including a first wordline 104, a second wordline 106 and a third wordline 108 (referred to hereinafter collectively as wordlines 104-108). At an intersection of a wordline 104, 106, 108 with bit line 102 are respective resistive memory circuits 110 (also referred to herein as filter circuits; see FIGS. 2 and 3A-3C, infra). Resistive memory circuits 110 are configured to output a signal on bit line 102 in conjunction with application of a read voltage Vread to bit line 102. As utilized herein, Vread is a voltage magnitude less than what is required to change a resistance state of a non-volatile resistive switching memory cell within resistive memory circuits 110, yet high enough to produce a measurably significant current through the resistive switching memory cell if the resistance state is (previously) set to a low resistance state. Respective signal outputs by resistive memory circuits 110 can map to logic states corresponding to multiplication components of the matrix product resulting from the matrix multiplication implemented by circuit 100. Adding these respective signal outputs can produce the matrix product itself. For instance, resistive memory circuit 114 can produce a signal output that has logical correspondence with a product of the D₀×F₀ multiplication component of the matrix multiplication. Likewise, resistive memory circuit 116 can produce a signal output that has logical correspondence with the D₁×F₁ multiplication component of the matrix multiplication and resistive memory circuit 118 can produce a signal output that has logical correspondence with the D₂×F₂ multiplication component of the matrix multiplication. Where the signal outputs are current responses on bit line 102, for example, a sum of the signal outputs on bit line 102 produces a current equal to the matrix product of the matrix multiplication.

To illustrate the logical correspondence between a resistive memory circuit 114 and a matrix multiplication component, consider the component D₀×F₀ in the binary context (though the subject disclosure is not limited to resistive memory circuits 110 that produce a signal output that maps to a binary numbering system; rather, analogous circuitry mapping other fixed-radix number systems such as quaternary, octal, decimal, hexadecimal, etc., numbering systems is considered to be within the scope of the present disclosure). The following truth table defines the results of dot-product multiplication of independent binary numbers utilized for data values of D₀ and F₀:

| | F₀ = 0 | F₀ = 1 |
|---|---|---|
| D₀ = 0 | 0 | 0 |
| D₀ = 1 | 0 | 1 |

Resistive memory circuit 114 can therefore be configured to produce a signal on bit line 102 that is low in response to D₀ or F₀ being low (being 0) and produce a signal that is high in response to D₀ and F₀ being high (being 1). Example circuits—though not exhaustive—are included as part of this disclosure. Other suitable circuits for replicating this truth table, known in the art or reasonably conveyed to one of ordinary skill in the art by way of the context disclosed herein are considered within the scope of the present disclosure. A similar circuit configured to produce a signal on bit line 102 that maps to truth tables for matrix multiplication components D₁×F₁ and D₂×F₂ can be provided for resistive memory circuit 116 and resistive memory circuit 118, respectively. In combination, resistive memory circuits 110 produce respective signals of matrix multiplication components that, when summed, produce a matrix product of the matrix multiplication.

Resistive memory circuits 110 can respectively comprise a resistive switching memory cell to store data values associated with the filter matrix: F₀, F₁, F₂. The resistive switching memory cell can be a non-volatile device, in various embodiments, to store the data values without continuous electrical power. In at least some embodiments, resistive memory circuits 100 can utilize volatile switching devices in combination with a non-volatile memory cell in some embodiments, or in lieu thereof in other embodiments.

FIG. 2 depicts a diagram of an example circuit 202 for implementing a multi-bit matrix multiplication 200 according to additional embodiments of the present disclosure. Matrix multiplication 200 illustrates a 1×3 data matrix: D multiplied by a 3×1 filter matrix: F. Further, D is a single-bit matrix with single-bit data values, and F is a multi-bit matrix with multi-bit data values. Specifically, each data value D₀, D₁, D₂ of the data matrix is a single-bit binary data value and each data value F₀, F₁, F₂ of the filter matrix is a four-bit binary data value.

Circuit 202 provides an example electronic structure to implement a matrix multiplication for the single-bit data matrix and multi-bit filter matrix and produce a matrix product. Circuit 202 comprises a plurality of wordlines, a plurality of bit lines, amplifier circuits 240 and a summing circuit 242. The plurality of wordlines includes a first wordline 204, a second wordline 206 and a third wordline 208 (referred to collectively as wordlines 204-208). The bit lines include a first bit line 214, a second bit line 216, a third bit line 218 and a fourth bit line 220 (referred to collectively as bit lines 214-220). Data values D₀, D₁, D₂ for the data matrix are entered onto wordlines 204, 206, 208, respectively, as an input to circuit 202.

Resistive memory circuits 210 (e.g., resistive memory circuit 230) are located at respective intersections of wordlines 204-208 and bit lines 214-220 of circuit 202. Resistive memory circuits can be programmed to store data values of the filter matrix F. In the 4-bit example of matrix multiplication 200, resistive memory circuits 210 connected to bit line 214 store least significant bit values of the multi-bit data values, resistive memory circuits 210 connected to bit line 216 store second-least significant bit values of the multi-bit data values, resistive memory circuits 210 connected to bit line 218 store second-most significant bit values of the multi-bit data values and resistive memory circuits 210 connected to bit line 220 store most significant bit values of the multi-bit data values. For example, a data value F₂ of the filter matrix having the four bits: a zeroth order bit F_{2,0}, a first order bit F_{2,1}, a second order bit F_{2,2}, and a third order bit F_{2,3} is stored at resistive memory circuits 210 connected to bit lines 214, 216, 218 and 220, respectively. To model the positional effect of the first, second and third order bits in the numbering system modeled by the circuit 202, amplifier circuits 240 are connected to bit lines 216, 218 and 220 having amplification values corresponding to a multiplication factor associated with the second-least significant bit, second-most significant bit and most significant bit of the numbering system. For a binary numbering system, an amplifier circuit that multiplies signals by a factor of 2 is connected to bit line 216, an amplifier circuit that multiplies signals by a factor of 4 is connected to bit line 218 and an amplifier circuit that multiplies signals by a factor of 8 is connected to bit line 220. These multiplication factors can have different values for a different numbering system (e.g., for a quaternary numbering system, the amplification factors can be ×4, ×16, ×64; and so on for other numbering systems).

Upon entering data values D₀, D₁, D₂ of data matrix D onto wordlines 204-208, resistive memory circuits 210 generate signals on bit lines 214-220 that have logical correspondence with matrix multiplication components of matrix multiplication 200. As an illustrative example, resistive memory circuits 210 connected to wordline 208 generate respective signals on bit lines 214-220 that logically correspond to matrix multiplication components: D₂×F_{2,0} on bit line 214, D₂×F_{2,1} on bit line 216, D₂×D_{2,2} on bit line 218 and D₂×D_{2,3} on bit line 220. Additionally, to model the multi-bit nature of filter matrix F, signals output onto bit lines 216, 218 and 220 are amplified by suitable amplifier circuits 240, and the respective amplified signals of bit lines 216, 218 and 220 are added to each other and to the signal output onto bit line 214 by a summing circuit 242 and output as a matrix product result of circuit 202, identified by SUM in FIG. 2.

One example circuit that can be utilized for resistive memory circuits 210 to generate a signal on a bit line 214-220 having a logical correspondence with a matrix multiplication component is illustrated by resistive memory circuit 230. Resistive memory circuit 230 is configured to generate such a signal having logical correspondence with a matrix multiplication component utilizing a binary numbering system, though other circuits can be incorporated for non-binary numbering systems. In addition, it should be understood that other example circuits could also be used as alternatives to resistive memory circuit 230 (e.g., see FIGS. 3A-3C, infra) for generating a signal with logical correspondence in a binary number system, and thus resistive memory circuit 230 is not provided as exclusive or exhaustive of such circuits.

As illustrated, resistive memory circuit 230 includes a wordline 232 of circuit 202 (e.g., wordline 204) coupled with a gate node of a transistor device 234. Transistor device 234 has a drain node coupled to a bit line of circuit 202 (e.g., bit line 214) and a source node coupled to a first terminal of a two-terminal resistive switching memory cell 236 (also referred to herein by the abbreviated terminology: ReMem). A second terminal of ReMem 236 is coupled to ground (or to a low voltage source relative to Vread applied to bit line 214). ReMem 236 is a non-volatile resistive switching device configured to switch between a high resistance state and a low resistance state, and is configured to maintain the high resistance state or the low resistance state in the absence of external power. By convention (though changeable) ReMem 236 stores a low ‘0’ bit value when in the high resistance state, and stores a high ‘1’ value when in the low resistance state. This stored value corresponds to a filter data matrix element: F_{0,0} of filter data matrix F.

To operate circuit 202 Vread is applied at bit line 214 (and bit lines 214-220) and signals representing data values of matrix D are input onto wordlines 204-208. In operation, when storing a high value (for F_{0,0}), ReMem 236 provides a low resistance path to ground (or low voltage), and when storing a low value (for F_{0,0}), ReMem 236 provides high resistance from ground (or low voltage). Meanwhile, transistor device 234 is responsive to a value of Do asserted on wordline 204 at the gate node of transistor device 234. When D₀ is a low value, transistor device 234 is deactivated and does provide electrical continuity between bit line 214 and ReMem 236. In contrast, when D₁ is a high value, transistor device 234 is activated and does provide electrical continuity between bit line 214 and ReMem 236. However, only when both D₀ has a high value (‘1’) and F_{0,0} stores a high value does resistive memory circuit 230 provide a low resistance path between bit line 214 and ground (or low voltage), and draw significant current on bit line 214 during operation of circuit 202. Thus, resistive memory circuit 230 operates consistent with the truth table described above at FIG. 1 for a matrix multiplication component: D₀×F_{0,0}, providing logical correspondence between a signal output on bit line 214 produced by resistive memory circuit 230 and a dot product of the matrix multiplication component: D₀×F_{0,0}.

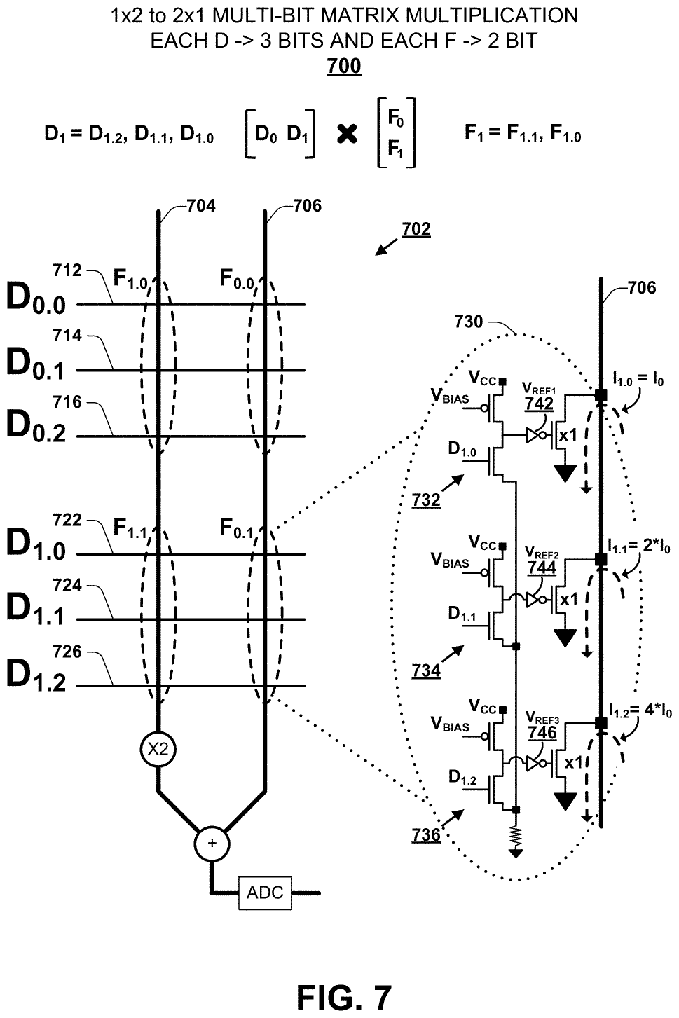

In alternative embodiments of the present disclosure, resistive memory circuits 210 can utilize a different resistive memory circuit in place of resistive memory circuit 230. Other resistive memory circuits can provide a signal output with similar logic performance as described for resistive memory circuit 230, while achieving differing benefits. For instance, some alternative resistive memory circuits can provide smaller area consumption, and therefore greater component density. Other resistive memory circuits can provide differing current draw capacities to model multi-bit data values for the D matrix, and yet others can achieve a combination of these characteristics (e.g., see FIG. 7, infra).

FIGS. 3A, 3B and 3C illustrate different example resistive memory circuits: 300, 310 and 330, respectively that model the logic of a matrix multiplication component for a binary numbering system, according to alternative or additional embodiments of the present disclosure. In some embodiments, a signal inverter (not depicted) could be employed in conjunction with a disclosed resistive memory circuit to match the truth table of FIG. 1, where suitable. The signal inverter could be utilized on an input to the memory circuit (e.g., on a wordline to invert a data value of data matrix D) or on a bit line to invert a signal response of the resistive memory circuit, where suitable.

As illustrated, resistive memory circuit 300 can be implemented in back-end of line logic with thin film processes, and consumes very small silicon space yielding high component density. In response to a read voltage Vread applied at bit line 306, and a data value for data matrix D applied on wordline 304, a current on bit line 306 reflects a dot product of the inverse data value for data matrix D (inverted data value or D) and a second data value of data matrix F stored at a ReMem device 302. For instance, where the data value F stored at ReMem device 302 is low (‘0’), then ReMem device 302 is in a high resistance state and current on bit line 306 is low for all values of D. Where the data value for D is high (‘1’), little voltage is dropped across ReMem 302 and thus no significant current on bit line 306 occurs for all values of F. In contrast, where the data value for D is low (‘0’) and F is high (‘1’), a voltage of approximately Vread is dropped across ReMem 302, which is in a low resistance state, producing current on bit line 306. Note that the truth table for this signal response is different from that in FIG. 1, as follows:

| | F = 0 | F = 1 |
|---|---|---|
| D = 0 | 0 | 1 |
| D = 1 | 0 | 0 |

Thus, to achieve the same truth table as FIG. 1, an inverter can be provided on wordline 304 to input D on wordline 304, obtaining the expected response on bit line 306 for the dot product multiplication provided in the truth table of FIG. 1:

| | F₀ = 0 | F₀ = 1 |
|---|---|---|
| D̅ = 0 | 0 | 0 |
| D̅ = 1 | 0 | 1 |

Referring to FIG. 3B, an alternative resistive memory circuit 310 is illustrated. Resistive memory circuit 310 includes a first transistor device 312 having a drain node connected to bit line 306 and having a source node connected to ground (or low voltage). A gate node of first transistor device 312 is connected to an output of an inverter, which is powered with a fixed Vcc voltage 314. When an input node 320 of the inverter is low, the fixed Vcc voltage 314 is applied at the gate node of first transistor device 312, activating first transistor device 312 resulting in a low resistance path between bit line 306 and ground (or low voltage). When input node 320 is high, the inverter outputs a low value at the gate node of first transistor device 312, deactivating first transistor device 312 and resisting current flow from bit line 306 to ground.

Resistive memory circuit 310 also includes a second transistor device 316 having a gate node connected to a data value of data matrix D, a drain node connected to input node 320 and a source node connected to a first terminal of a ReMem device 311. A second terminal of ReMem device 311 is connected to ground (or a low voltage). A PMOS transistor device 318 is provided having a drain node connected to input node 320, a source node connected to Vcc voltage and a gate node. When the gate node of PMOS transistor device 318 is unbiased (or held low), Vcc is applied to input node 320 to maintain a low signal at the output of the inverter and at the gate node of first transistor device 312. Thus, when PMOS gate node of third transistor device 318 is unbiased, first transistor device 312 is maintained in a deactivated state.

A data value of filter matrix F is stored at ReMem 311. When the data value of F is low ‘0’, ReMem 311 is in a high resistance state insulating the source node of second transistor device 316 from ground (or low voltage). When the data value of F is high ‘1’, ReMem 311 is in a low resistance state and electrically connects the source node of second transistor device 316 to ground (or low voltage).

To operate resistive memory circuit 310, a positive bias voltage: Vbias is applied to the gate node of PMOS transistor device 318. Vbias deactivates PMOS transistor device 318 and isolates input node 320 from Vcc. Thus, input node 320 retains charge previously supplied by Vcc but is not driven to the Vcc voltage. With Vbias supplied to the gate node of PMOS transistor device 318, the data value of data matrix D is supplied to second transistor 316. If the value of D is low ‘0’, second transistor device 316 is deactivated and electrically insulates input node 320 from ReMem 311. As a result, charge previously supplied by Vcc to input node 320 remains at input node 320 for all values of F stored at ReMem 311 when the data value of data matrix D is low. When the data value of data matrix D is high ‘1’, second transistor device 316 is activated and input node 320 is electrically coupled to the first terminal of ReMem 311. If the data value of F is low, ReMem 311 is in a high resistance state and no significant charge from input node 320 is drained to ground (or low voltage), and thus first transistor device 312 remains deactivated. In contrast, if the data value of F is high ‘1’ when the data value of data matrix D is high ‘1’, ReMem 311 is in a low resistance state and input node 320 is pulled down to ground (or low voltage) through the second terminal of ReMem 311. As a result, Vcc 314 is output by the inverter to the gate node of first transistor device 312, thereby activating the first transistor device 312. With Vread applied to bit line 306, activation of first transistor device 312 causes current to flow from bit line 306 to ground at the source node of first transistor device 312. Thus, the signal output on bit line 306 matches the truth table of FIG. 1: when D=0 the signal output is low (no current) for all values of F, and when F=0 the signal output is low for all values of D. In contrast, when D=1 and F=1, the signal output on bit line 306 is high (current flows).

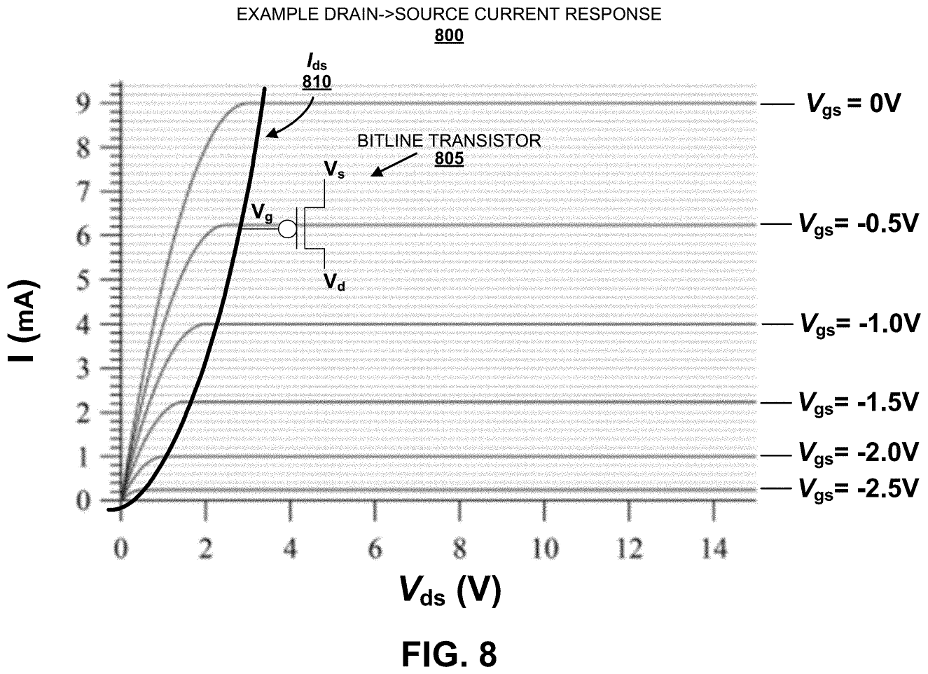

Resistive memory circuit 330, referring now to FIG. 3C, comprises a first transistor device 332 having a drain node connected to bit line 306, a source node connected to ground (or low voltage) and a gate node connected to an output of an inverter. The inverter has an input node 340 and an output node connected to the gate node of first transistor device 332. When input node 340 is low, a selectable reference voltage: Vref 334 is applied to the gate node of first transistor device 332. Additionally, first transistor device 332 can have a channel conductivity dependent on a magnitude of the reference voltage Vref 334 (e.g., see FIG. 8, infra, for an example I-V response of a transistor in response to a range of gate-source voltage values: Vgs). In one or more embodiments, Vref 334 and first transistor device 332 can be selected so that channel conductivity values (and therefore current magnitudes) in response to select Vref 334 values are defined by the relationship: Cx=C₀*N^{x} where x is a number of distinct channel conductivity values, Cx is conductivity of an x^{th} conductivity value, C₀ is a zeroth order channel conductivity value where x=0, and N is a radix (or factor) of a positional numbering system modeled by the channel conductivity values. Thus, for example, for a binary numbering system N=2, and Cx=C₀*2^{x}. Likewise, for a quaternary numbering system N=4, and Cx=C₀*4^{x}, and so forth.

Resistive memory circuit 330 can operate similar to resistive memory circuit 310 described above. For instance, upon application of Vbias to a gate node of a PMOS transistor 338, a fixed Vcc voltage is isolated from input node 340 by the deactivated PMOS transistor 338. A data value for a filter matrix F is stored at ReMem 331, and a data value for a data matrix D is input on a wordline coupled to a gate node of a second transistor device 336. Input node 340 remains high for all F=0 and for all D=0 data values. When F=1 and D=1, a selected voltage value Vref 334 is applied to the gate node of first transistor device 332. This voltage value can be selected depending on whether resistive memory circuit 330 is coupled to a zeroth order, first order, second order, . . . z^{th} order bit line of a matrix multiplication circuit, as described in more detail herein (e.g., see FIG. 7, infra).

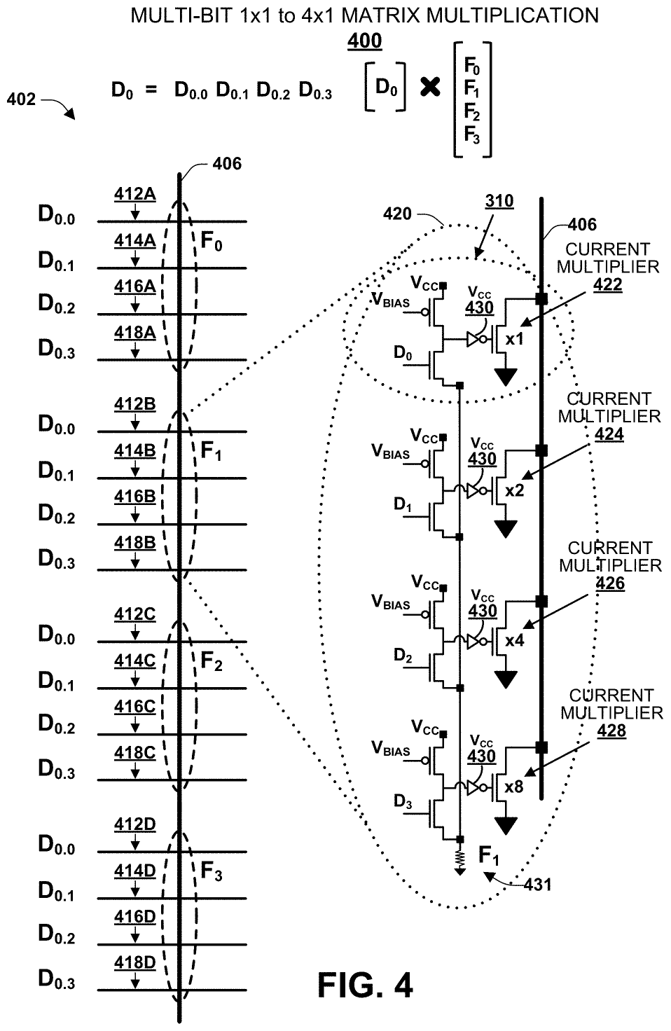

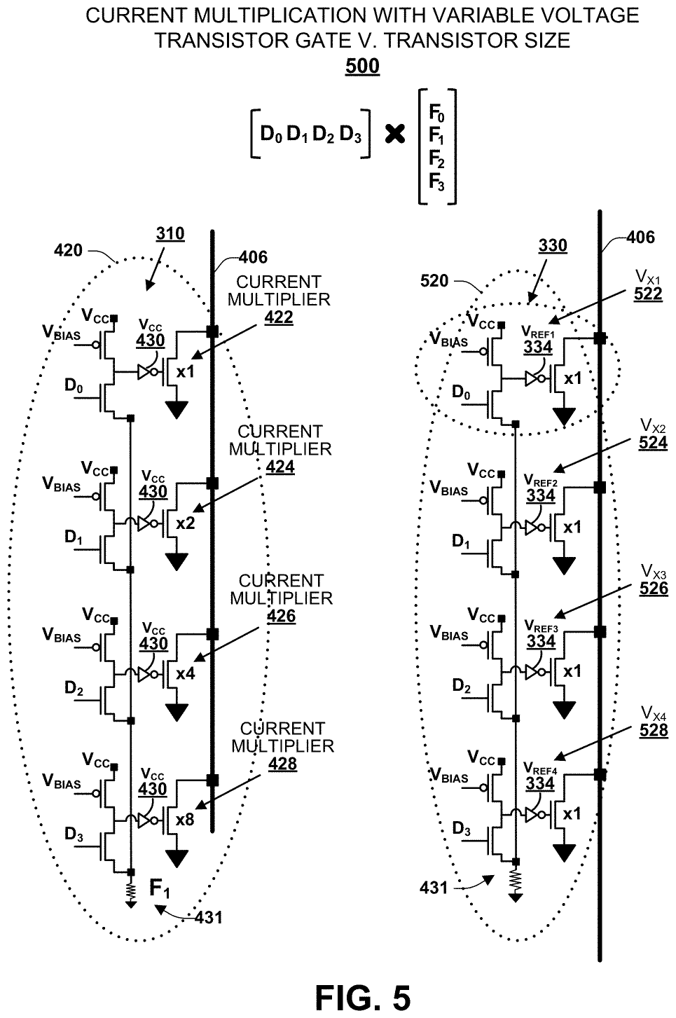

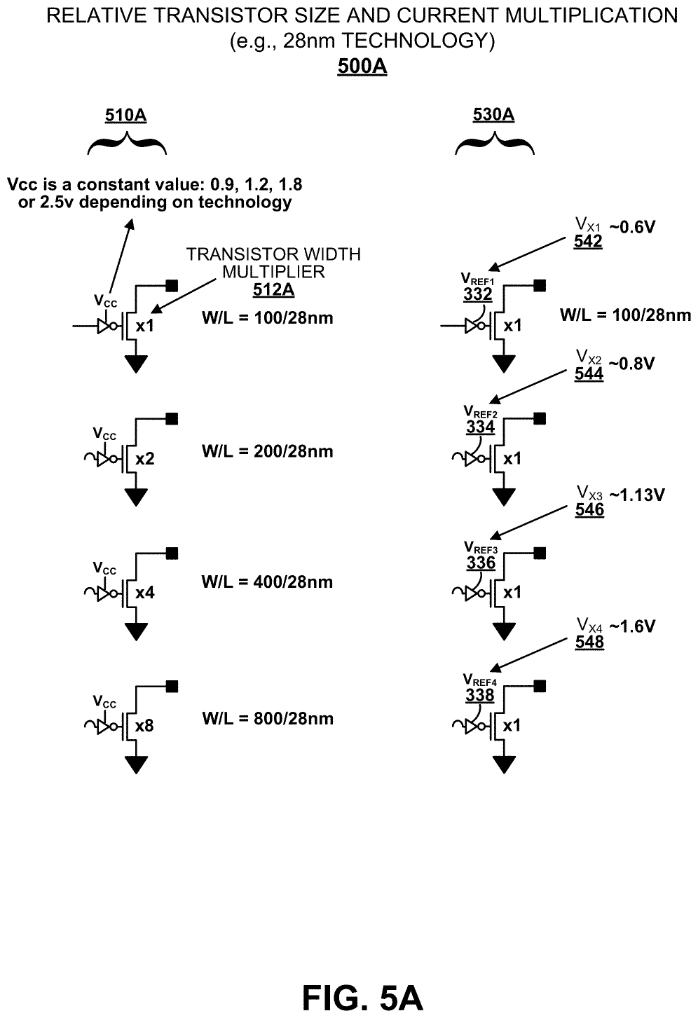

FIG. 4 illustrates an example circuit 402 for implementing a matrix multiplication 400 according to further embodiments of the present disclosure. Matrix multiplication 400 includes a data matrix D with a single multi-bit data value and a filter matrix F with four single-bit data values as well. To model the four-bit data value of the data matrix D, four wordlines are provided for each data value of filter matrix F, as illustrated. For filter matrix data value F₁, bits of the four-bit data value D_{0.0}, D_{0.1}, D_{0.2}, D_{0.3} are input on wordlines 412B, 414B, 416B, 418B, respectively, to one of four resistive memory circuits 310. The filter data value Fi is stored by circuit 420 at a non-volatile resistive switching memory cell 431, to which respective second transistors 316 of the resistive memory circuits 310 are connected. When activated as described above with FIG. 3B (e.g., when F=0 and D_{0.0} is 0), a fixed Vcc 430 voltage is applied by a resistive memory circuit 310 to a gate node of an associated first transistor devices 312. To model the factorial relationship of four-bit data values in a binary numbering system, first transistor devices 312 are selected upon manufacture to have channel conductivity (and channel current) of different values that match the factorial relationship. For a binary numbering system respective values for each of the first transistor devices 312 are indicated by respective current multiplier values: x1 current 422, x2 current 424, x4 current 426, and x8 current 428. As illustrated in FIG. 5, infra, these current values can be achieved in response to a fixed Vcc 430 voltage by sizing a channel width of each of the first transistor devices 312 equal to the current multiplier values. In alternative embodiments, current values can be achieved post-manufacture by control of voltage applied to a first transistor device (see FIGS. 5, 6 and 7, infra).

Circuit 420 can operate by separate resistive memory circuits 310 included within circuit 420 generating respective currents (or no current) on bit line 406. When current is generated, it is in proportion to the current multiplier value 422, 424, 426, 428 associated with a particular resistive memory circuit 310. In general, current is generated or not generated based on respective values of the D_{0.0}, D_{0.1}, D_{0.2}, D_{0.3} signals and based on a value stored at non-volatile resistive memory cell 431 for the value of F₁. Where F₁ is 0, no memory circuit 420 draws current on bit line 406. Where F₁ is 1, memory circuits having an input data matrix value that is also ‘1’ will generate current on bit line 406. The amount of current is determined by the current multiplier value 422, 424, 426, 428 of the respective resistive memory circuit 430, multiplied by a default current value or C₀. Thus, if D_{0.3} is 1 when F₁ is also 1, the resistive memory circuit 310 coupled to wordline 418B will produce a current having magnitude of 8× the base current: C₀. If D_{0.2} is 1 when F₁ is also 1, the resistive memory circuit 310 coupled to wordline 416B will produce a current having magnitude 4× C₀, and so on. More generally, channel conductance of resistive memory circuits 310 of circuit 420 can have conductance values defined by the following relationship:

Cx=C₀*N^{x}

where C₀ is base conductance, and Cx is a conductance of the x^{th} resistive memory circuit 310 and N is a radix of a numbering system (e.g., N=2 for the binary numbering system) modeled by the channel conductance of resistive memory circuits 310.

FIG. 5 depicts example circuits for current multiplication 500 according to alternative or additional embodiments of the present disclosure. Particularly, current multiplication 500 compares schematic diagrams of circuit 420 achieving current multiplication by increasing transistor width with a fixed gate voltage Vcc, and circuit 520 achieving current multiplication by variable transistor gate voltage. Circuit 520 can comprise resistive memory circuits 330 having respective transistor devices coupled to bit line 406. Moreover, these transistor devices can have a minimum transistor width, and achieve different channel conductance values by selection of different voltages at gate nodes of the transistor devices. These different voltages can be achieved by providing a selectable reference voltage Vref to respective inverter devices coupled to the gate nodes. The reference voltages V_{ref1} 522, V_{ref2} 524, V_{ref3} 526, V_{ref4} 528 (referred to hereinafter collectively as reference voltages 522-528) have voltage magnitudes selected to achieve target channel conductance values. For instance, the voltage values can be selected to achieve conductance values defined by the relationship:

Cx=C₀*N^{x}

with parameters C₀, Cx and N as defined above. Accordingly, resistive memory circuits 330 can achieve current responses on bit line 406 analogous to those of circuit 420, without increasing the size of transistors connected to bit line 406. This can enhance memory density by maintaining minimum transistor size for transistors utilized for resistive memory circuits 330.

FIG. 5A depicts example relative transistor size and current multiplication 500A for an example transistor device technology, according to further embodiments of the present disclosure. The numbers provided for the device characteristics in the example of FIG. 5A are for 28 nm semiconductor technology; however, it should be understood that these quantitative characteristics are illustrative only and other technology node sizes and indeed other 28 nm technology devices can have different quantities for the example device characteristics within the scope of the present disclosure.

Resistive memory circuits 510A and 530A illustrate a portion of the components of respective resistive memory circuits 510A and 530A disclosed, for example, at FIG. 3, supra. Specifically, resistive memory circuits 510A and 530A include respective transistor devices, inverters and voltage sources that match those for the respective resistive memory circuits 310 and 330. Resistive memory circuits 510A include an inverter with fixed magnitude voltage source Vcc that, when an input of the inverter is a high signal, outputs the fixed magnitude Vcc voltage to a gate node of a transistor device of resistive memory circuits 510A. Channel conductance of the transistor devices of resistive memory circuits 510A are controlled by physical width of a channel region (source to drain) of the transistor devices formed upon fabrication of such devices. Accordingly, the channel conductance in response to Vcc is fixed upon fabrication. The x1 transistor device has a nominal transistor width W₀ of about 100 nm, and the length is defined by a technology node for this integrated circuit technology, in this example 28 nm. The nominal transistor width W₀ correlates to a nominal channel conductance C₀ for x1 transistor device as well. The x2 transistor device has twice the nominal transistor width 2*W₀ of about 200 nm, and has a channel conductance of approximately 2× the channel conductance of the xl transistor device 2*C₀. Likewise, the x4 transistor device has about four times the nominal transistor width 4*W₀ and about four times the nominal channel conductance 4*C₀, whereas the x8 transistor device has approximately eight times the nominal transistor width 8*W₀ and about eight times the nominal channel conductance 8*C₀. Note that the channel width is fixed upon fabrication and cannot be changed post-fabrication. However, these widths can be different for transistor device circuits modeling other non-binary numbering systems, such as quaternary or decimal systems, and so forth.

Resistive memory circuits 530A include an inverter with selectable magnitude voltage source Vref, and respective transistor devices with a nominal transistor width only (e.g., W₀˜100 nm can be applicable for a 28 nm technology node). The transistor devices for resistive memory circuits 530A achieve variable channel conductance in response to different voltage magnitudes applied to the gate nodes thereof, specifically: V_{ref1} 542, V_{ref2} 544, V_{ref3} 546 and V_{ref4} 548 (referred to hereinafter collectively as Vref sources 542-548). In the example illustrated by FIG. 5A (see also the current-voltage response of FIG. 8, infra) a voltage magnitude V_{X1} 542 of about 0.6 volts can achieve a nominal channel conductance C₀. A voltage magnitude V_{X2} 544 of about 0.8 volts can achieve a channel conductance of about 2*C₀, a voltage magnitude V_{X3} 546 of about 1.1 volts can achieve a channel conductance of about 4*C₀ and a voltage magnitude V_{X4} 548 of about 1.6 volts can achieve a channel conductance of about 8*C₀. Since the transistor width remains at the nominal value (e.g., ˜100 nm), resistive memory circuits 530A consume less silicon area on a substrate of a die than the resistive memory circuits 510A. Though resistive memory circuits 510A can be operated by a fixed Vcc voltage, they consume greater silicon substrate space. Accordingly, resistive memory circuits 530A can achieve higher component density by consuming less silicon substrate area.

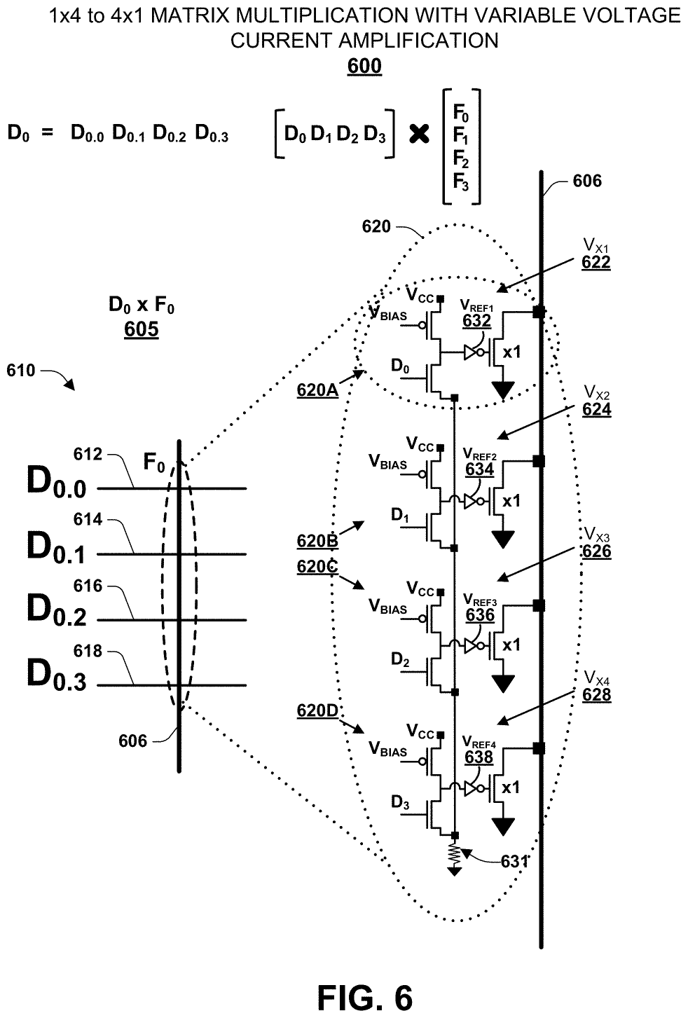

FIG. 6 illustrates a diagram of an example matrix multiplication with variable voltage current amplification 600 according to further embodiments of the present disclosure. A circuit 610 is provided for implementing a dot product result of a D₀×F₀ component 605 of a 1×4 to 4×1 matrix multiplication, where each data value of data matrix D is a four-bit data value, and each data value of filter matrix F is a one-bit value. Data value D₀ includes bits: D_{0.0}, D_{0.1}, D_{0.2} and D_{0.3} that are input as signals on wordlines 612, 614, 616 and 618 respectively (referred to hereinafter collectively as wordlines 612-618). Circuit 620 receives the data matrix D signals and generates respective output signals on a bit line 606. A default current value Io associated with a first portion 620A of circuit 620 is responsive in part to bit D_{0.0}. Depending on a first value of bit D_{0.0} and a second value of F₀ stored at non-volatile resistive memory cell 631, the first portion 620A of circuit 620 can draw no current on bit line 606 or draw I₀ current on bit line 606 in response to a default voltage: V_{X1} 622 applied to a first transistor connected to bit line 606. Amplified current values associated with the D_{0.1} bit (e.g., 2*I₀ for a binary numbering system), the D_{0.2} bit (e.g., 4*I₀) and the D_{0.3} bit (e.g., 8*I₀) can be drawn on bit line 606 by respective portions 620B, 620C, 620D of circuit 620. The different amplified current values are realized from different voltage magnitudes V_{X2} 624, V_{X3} 626 and V_{X4} 628 applied to gate nodes of respective first transistor devices of the portions 620B, 620C, 620D of circuit 620 that are coupled to bit line 606. Summation of these currents represents a dot product result of the D₀×F₀ component 605 of the 1×4 to 4×1 matrix multiplication with variable voltage current amplification 600 illustrated by FIG. 6.

FIG. 7 illustrates a dual multi-bit matrix multiplication 700 according to still further embodiments of the present disclosure, in which a first multi-bit matrix is multiplied by a second multi-bit matrix. In more detail, the dual multi-bit matrix multiplication 700 is a 1×2 data matrix: D multiplied by a 2×1 filter matrix: F. Each data value of the D matrix comprises 3 bits, and each data value of the F matrix comprises 2 bits. This dual multi-bit matrix multiplication 700 is implemented by circuit 702, including a pair of bit lines 704, 706 and two pairs of three wordlines (six wordlines in total), including: wordline 712, wordline 714 and wordline 716 as part of the first pair of wordlines, and wordline 722, wordline 724 and wordline 726 as part of the second pair of wordlines (referred to hereinafter collectively as: wordlines 712-726). The first pair of bitlines receive signals representing a first 3-bit data value D₀ of matrix D (D₀=D_{0.2}, D_{0.1}, D_{0.0}), and the second pair of bitlines receive signals representing a second 3-bit data value D₁ (D₁=D_{1.2}, D_{1.1}, D_{1.0}) of matrix D. 2-bit data values representing the filter matrix F (F₀=Fr₀, F_{0.0} and F₁=F_{1.1}, F_{0.1}) are stored at circuits 730 connected to bit lines 704 and 706 and respective pairs of the wordlines. Circuits 730 allocated to the F₀ data value are coupled to the first pair of wordlines (including wordlines 712, 714, 716) whereas circuits 730 allocated to the F₁ data value are coupled to the second pair of wordlines (including wordlines 722, 724, 726). Non-volatile resistive memory cells 736 (ReRAM cells) associated with respective circuits 730 are configured to store bits representing the data values corresponding to filter matrix F.

An example circuit 730 connected to bit line 706 is illustrated in FIG. 7. As illustrated, circuit 702 of FIG. 7 incorporating circuit 730 demonstrates a 3-bit matrix multiplication and accumulation function. The 2×2 3-bit MAC has 4 ReRAM to enable or disable the multiplication of each 3-bit binary input vector (e.g., from Dn.m inputs). Specifically: each circuit 730 includes one ReRAM for four total ReRAM in the depicted circuit 702. Table 1 provides a multiplied and accumulated current for a kernel matrix multiplied by the analog represented array (note that the resistive memory cell 736 of circuit 730 for the F_{0.1} filter is in an off state yielding a 0,0,0 vector for the F_{0.1} filter).

Circuit 700 includes three portions 732, 734, 736 respectively connected to a wordline of the second pair of wordlines. Specifically, wordline D_{1.0} 722 is connected to first portion 732, wordline D_{1.1} is connected to second portion 734 and wordline D_{1.2} 726 is connected to third portion 736, as illustrated. A non-volatile resistive switching memory cell 736 stores a bit F_{0.1} of the F₁ data value of filter matrix F. A second bit F_{1.1} of the F₁ data value is stored by a circuit 730 coupled to bit line 704. Likewise, a first bit F_{0.0} of the F₀ data value is stored by a circuit coupled to bit line 706 and a second bit F_{1.0} of the F₀ data value is stored by a circuit coupled to bit line 704.

TABLE 1
Example Multiplied and Accumulated Current
Output by ADC of Circuit 702

| | | | | | F1.0 | | F0.0 |
|---|---|---|---|---|---|---|---|
| | | | | | 4 | | 4 |
| | | | | | 2 | | 2 |
| | | | | | 1 | | 1 |
| | | | | Sum | 6 | | 6 |
| Dn | Dn.0 | Dn.1 | Dn.2 | | | | |
| 0 | 1 | 1 | 0 | | F1.1 | | F0.1 |
| 1 | 1 | 0 | 1 | | 4 | | 0 |
| | | | | | 2 | | 0 |
| | | | | | 1 | | 0 |
| | | | | Sum | 5 | | 0 |
| | | | | | Bitline 704 | | Bitline 706 |
| | | Total BL | | | 11 | | 6 |
| | | current | | | | | |
| | | | | | Total= | 17 | uA |

Each portion 732, 734, 736 of circuit 730 comprises a transistor device having respective channel nodes (source or drain) coupled to bit line 706. Each such transistor device has a width xl defined by a single technology node dimension. A variable reference voltage is provided to gate nodes of the respective transistor devices. Respective reference voltages: V_{ref1} 742, V_{ref2} 744 and V_{ref3} 746 output different voltage values that are correlated to a bit multiplier associated with a multi-bit numbering system modeled by the data values of data matrix D. For a binary numbering system modeled by data values of data matrix D, V_{ref1} 742 is selected to generate a base current magnitude I₀ at bit line 706 upon activation of the transistor device of portion 732, V_{ref2} 744 is selected to generate two times the base current 2*I₀ on the bit line 706 upon activation of the transistor device of portion 734, and V_{ref3} 746 is selected to generate four times the base current 4*I₀ on the bit line 706 upon activation of the transistor device of portion 736. Described differently, the transistor gates of NMOS transistors coupled to bitline 706 of portions 732, 734 and 736 are biased by V_{ref1} 742, V_{ref2} 744 and V_{ref3} 736, respectively, such that each V_{ref} provides a binary weighted conductance to the NMOS transistor embodying the transistors coupled to bitline 706. As illustrative examples: V_{ref1} provides about 1 μA conductance, V_{ref2} 744 provides about 2 μA conductance and V_{ref3} 746 provides about 4 μA conductance. Other voltage values to cause different base current multipliers at bit line 706 can be implemented for non-binary numbering systems.

Based on the applied D_{1.0}, D_{1.1}, D_{1.2} logic states bitline 706 yields current (associated with filter F_{0.1}) that could have states defined by: 0 μA, 1 μA, 2 μA, 3 μA, 4 μA, 5 μA, 6 μA, up to 7 μA (e.g., D_{0.0}=0, D_{0,1}=1, D_{0.2}=1 yields 6 μA on bitline 706 associated with Filter F_{0.1}). By enabling the ReRAM 736 of circuit 730 (e.g., programming the ReRAM to the low resistance state) F_{0.0} and F_{0.1} will generate analog current levels on the bitline 706 from 0 to 14 μA. By converting the current to voltage and digitizing the voltage to a binary state the resulting value represents a multiply accumulation function of that (filter F) vector with the content of the digital input vector (matrix D).

FIG. 8 illustrates an example current response 800 of an example transistor device according to one or more embodiments of the present disclosure. The transistor device can be a bitline transistor 805 coupled to a bit line of a disclosed circuit for drawing current on the bit line proportional to a voltage applied to a gate node of bitline transistor 805. Moreover, bitline transistor 805 can have a single transistor width xl defined by a technology node dimension of photolithographic equipment utilized to mask and etch the bitline transistor 805. As illustrated (but non-limiting) examples: for a 56 nm technology node the bitline transistor can have a 56 nm width; for a 28 nm technology node the bitline transistor can have a 28 nm width; for a 22 nm technology node the bitline transistor can have a 22 nm width, and so forth. Current response 800 depicts saturation current values (along the Y axis) as a function of drain-source voltage Vₐₛ (along the X axis), for different gate-source voltage values V_{gs}. I_{ds} 810 illustrates an example drain-source current of bitline transistor 805 as a function of varying V_{gs} voltage. The correlation between drain-source current and V_{gs} illustrated by I_{ds} 810 can be utilized for selecting reference voltages (e.g., V_{ref1} 742, V_{ref2} 744, V_{ref3} 746 of FIG. 7, infra among others) applied to bitline-connected transistors to control current output by those transistors, such that current drawn by a set of transistors (e.g., I_{1.0}, I_{1.1} and I_{1.2} of FIG. 7, infra) are respectively multiplied in a manner that models a numbering system. For example, a set of transistors modeling a binary numbering system can draw current values respectively multiplied by a factor of 2 relative to other such current values. More generally, the current magnitudes Ix associated with a set of x transistors, where x has integer values from 0 to a positive number, can have magnitudes represented by the following relationship:

I_{X}I₀*N^{x}

where I₀ is a smallest conductance magnitude of the plurality of conductance values and N is a radix of a numbering system modeled by the set of transistors.

The diagrams included herein are described with respect to interaction between several memory cells, electronic circuits comprising a memory cell, or memory architectures. It should be appreciated that such diagrams can include those memory cells, electronic circuits and architectures specified therein, some of the specified memory cells/electronic circuits/architectures, or suitable alternative or additional memory cells/electronic circuits/architectures. Sub-components of disclosed circuits or architectures can also be implemented as electrically connected to other sub-components rather than included within a parent architecture. Moreover, some of the disclosed embodiments can be implemented as part(s) of other disclosed embodiments where suitable. Additionally, it is noted that one or more disclosed processes can be combined into a single process providing aggregate functionality. For instance, a program process can comprise an erase process, or vice versa, to facilitate programming and erasing a semiconductor cell by way of a single process. In addition, it should be appreciated that respective rows of multiple cell memory architectures can be erased in groups (e.g., multiple rows erased concurrently) or individually. Moreover, it should be appreciated that multiple memory cells on a particular row can be read or programmed in groups (e.g., multiple memory cells read/programmed concurrently) or individually. Components of the disclosed architectures can also interact with one or more other components not specifically described herein but known by those of skill in the art or made evident by way of the context provided herein.

In view of the exemplary diagrams described above, process methods that can be implemented in accordance with the disclosed subject matter will be better appreciated with reference to flow charts. While for purposes of simplicity of explanation, the methods are shown and described as a series of blocks, it is to be understood and appreciated that the claimed subject matter is not limited by the order of the blocks, as some blocks can occur in different orders or concurrently with other blocks from what is depicted and described herein. Moreover, not all illustrated blocks can be required to implement the methods described herein. Additionally, it should be further appreciated that the methods disclosed throughout this specification are capable of being stored on an article of manufacture to facilitate transporting and transferring such methodologies to an electronic device. The term article of manufacture, as used, is intended to encompass a computer program accessible from any computer-readable device, device in conjunction with a carrier, or storage medium.

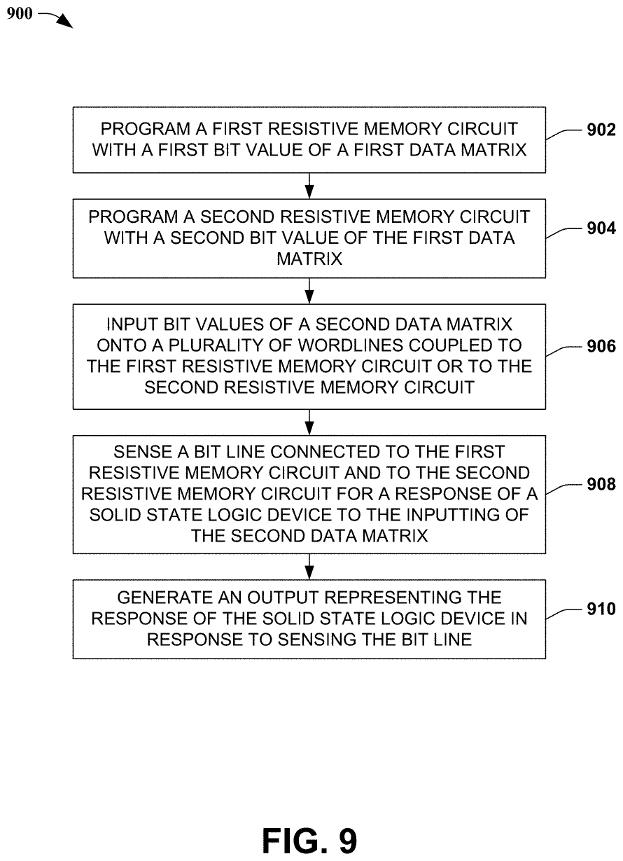

Referring to FIG. 9, a method 900 for operating a circuit is disclosed. Method 900 can comprise programming a first resistive memory circuit with a first data value of a first data matrix. The first resistive memory circuit can comprise a non-volatile two-terminal resistive switching memory cell for storing the first data value, and a transistor device directly or indirectly responsive to the first data value stored at the non-volatile two-terminal resistive switching memory cell. At 904, method 900 can comprise programming a second resistive memory circuit with a second bit value of the first data matrix. At 906, method 900 can comprise inputting bit values of a second data matrix onto a plurality of wordlines coupled to the first resistive memory circuit or to the second resistive memory circuit. At 908, method 900 can additionally comprise sensing a bit line connected to the first resistive memory circuit and to the second resistive memory circuit for a response of a solid state logic device to the inputting of the second data matrix onto the plurality of wordlines. In one or more embodiments, the solid state logic device comprises the first resistive memory circuit, the second resistive memory circuit, the bit line and the plurality of word lines. At 910, method 900 can further comprise generating an output representing the response of the solid state logic device in response to sensing the bit line. In some embodiments, the transistor device of the first resistive memory circuit is directly or indirectly responsive to the first data value for generating a portion of the output on the bit line.

In one or more embodiments, the first resistive memory circuit can further comprise a second transistor device directly or indirectly responsive to the first data value stored at the non-volatile two-terminal resistive switching memory cell for generating a second portion of the output on the bit line. In further embodiments, a data value of the second data matrix is a multi-bit data value comprising a first order bit, and comprising a second order bit that is equal to a product of the first order bit and a multiplier. According to alternative or additional embodiments, method 900 can further comprise entering the first order bit of the multi-bit data value onto a wordline of the plurality of wordlines coupled to the first resistive memory circuit, and entering the second order bit of the multi-bit data value onto a second wordline of the plurality of wordlines coupled to the first resistive memory circuit. Still further, the transistor device can be responsive to a value of the first order bit of the multi-bit data value and to the first data value stored at the non-volatile two-terminal resistive switching memory cell to selectively produce a first current on the bit line. Additionally, the second transistor device can be responsive to a second value of the second order bit and to the first data value stored at the non-volatile two-terminal resistive switching memory cell to selectively produce a second current on the bit line. In an embodiment(s), the second current on the bit line produced by the second transistor device is equal to or approximately equal to a product of the first current on the bit line produced by the first transistor device and a multiplier. As one example, the data value of the second data matrix is a positional notation number comprising the first order bit and the second order bit and wherein the multiplier is a base (or radix) of the positional notation number. For instance, where the positional notation number is a binary number, the multiplier is two.

In alternative or additional embodiments of the present disclosure, method 900 can comprise sensing a first magnitude on the bitline provided by the portion of the output on the bit line in response to the first data value having a first binary state. Alternatively or in addition, method 900 can comprise sensing a second magnitude on the bit line provided by the portion of the output on the bit line in response to the first data value having a second binary state.

In a further embodiment(s), method 900 can comprise applying a reference voltage to the first memory circuit, wherein the reference voltage is transferred to a control gate of the transistor device in response to the first data value causing the non-volatile two-terminal resistive switching memory cell to have a low resistance state and in response to a value of the first order bit entered onto the wordline. Additionally, method 900 can comprise applying a second reference voltage to the first memory circuit, wherein the second reference voltage is transferred to a control gate of the second transistor device in response to the first data value causing the non-volatile two-terminal resistive switching memory cell to have the low resistance state and in response to a second value of the second order bit entered onto the second wordline. In at least one embodiment, the magnitude of the second reference voltage is different from a magnitude of the first reference voltage, and the magnitude of the second reference voltage and the magnitude of the first reference voltage can be selected to cause the second transistor device to have a channel conductance approximately twice the channel conductance of the transistor device.

### Example Operating Environments

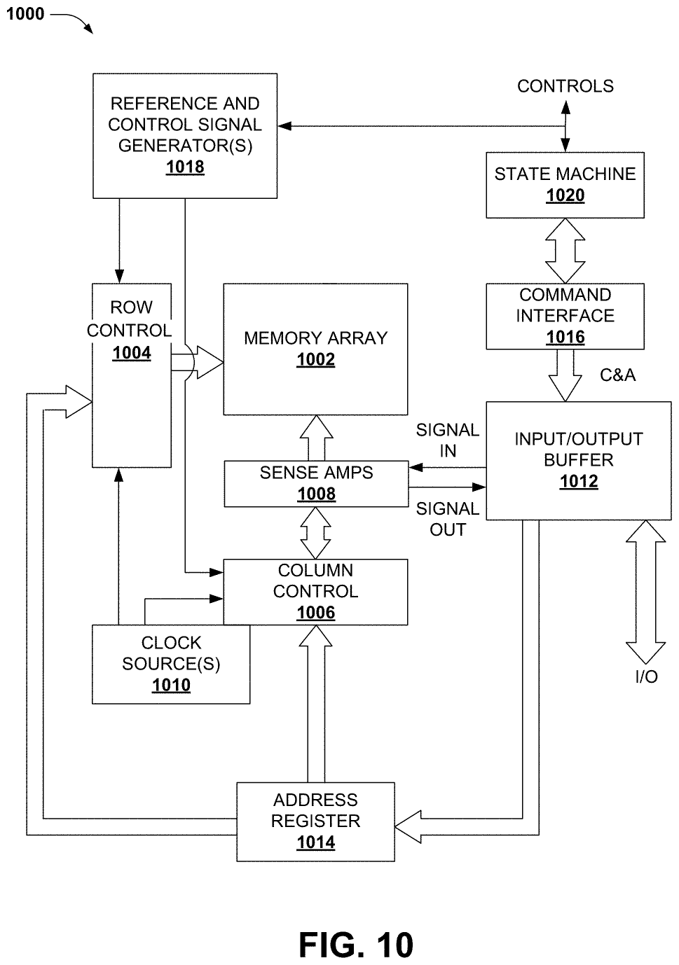

FIG. 10 illustrates a block diagram of an example operating and control environment 1000 for a memory array 1002 of a memory device according to aspects of the subject disclosure. Control environment 1000 and memory array 1002 can be formed within a single semiconductor die in some embodiments, although the subject disclosure is not so limited and in other embodiments some components of control environment 1000 can be formed on a separate semiconductor die. In at least one aspect of the subject disclosure, memory array 1002 can comprise memory selected from a variety of memory cell technologies. In at least one embodiment, memory array 1002 can comprise a two-terminal memory technology, arranged in a compact two or three-dimensional architecture. Suitable two-terminal memory technologies can include resistive-switching memory, conductive-bridging memory, phase-change memory, organic memory, magneto-resistive memory, or the like, or a suitable combination of the foregoing. In a further embodiment, the two-terminal memory technology can be a two-terminal resistive switching technology.

A column controller 1006 and sense amps 1008 can be formed adjacent to memory array 1002. Moreover, column controller 1006 can be configured to activate (or identify for activation) a subset of bit lines of memory array 1002. Column controller 1006 can utilize a control signal provided by a reference and control signal generator(s) 1018 to activate, as well as operate upon, respective ones of the subset of bitlines, applying suitable program, erase or read voltages to those bitlines. Non-activated bitlines can be kept at an inhibit voltage (also applied by reference and control signal generator(s) 1018), to mitigate or avoid bit-disturb effects on these non-activated bitlines.

In addition, operating and control environment 1000 can comprise a row controller 1004. Row controller 1004 can be formed adjacent to and electrically connected with word lines of memory array 1002. Also utilizing control signals of reference and control signal generator(s) 1018, row controller 1004 can select particular rows of memory cells with a suitable selection voltage. Moreover, row controller 1004 can facilitate program, erase or read operations by applying suitable voltages at selected word lines.

Sense amps 1008 can read data from, or write data to, the activated memory cells of memory array 1002, which are selected by column control 1006 and row control 1004. Data read out from memory array 1002 can be provided to an input/output buffer 1012. Likewise, data to be written to memory array 1002 can be received from the input/output buffer 1012 and written to the activated memory cells of memory array 1002.

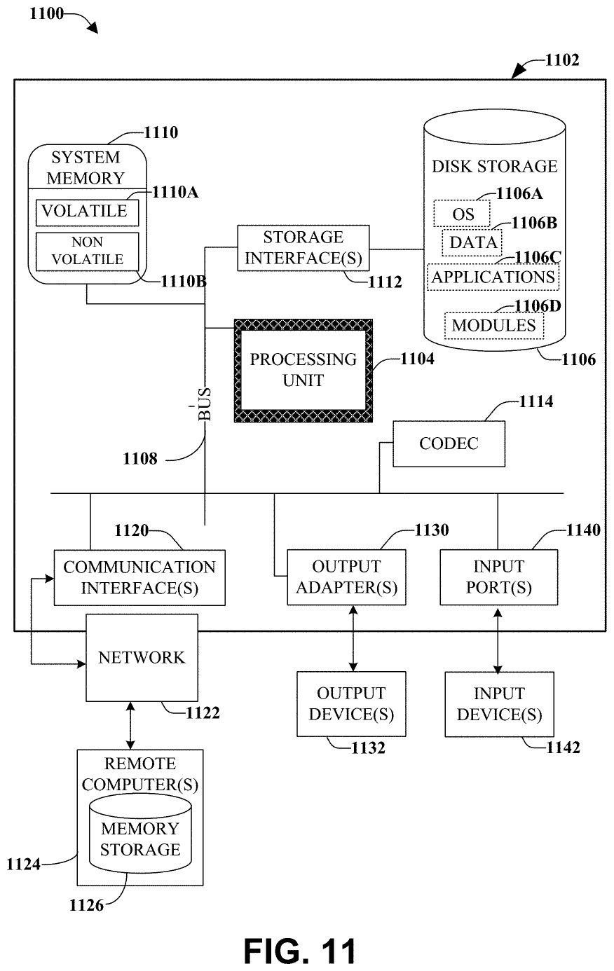

A clock source(s) 1010 can provide respective clock pulses to facilitate timing for read, write, and program operations of row controller 1004 and column controller 1006. Clock source(s) 1010 can further facilitate selection of word lines or bit lines in response to external or internal commands received by operating and control environment 1000. Input/output buffer 1012 can comprise a command and address input, as well as a bidirectional data input and output. Instructions are provided over the command and address input, and the data to be written to memory array 1002 as well as data read from memory array 1002 is conveyed on the bidirectional data input and output, facilitating connection to an external host apparatus, such as a computer or other processing device (not depicted, but see e.g., computer 1102 of FIG. 11, infra).

Input/output buffer 1012 can be configured to receive write data, receive an erase instruction, receive a status or maintenance instruction, output readout data, output status information, and receive address data and command data, as well as address data for respective instructions. Address data can be transferred to row controller 1004 and column controller 1006 by an address register 1014. In addition, input data is transmitted to memory array 1002 via signal input lines between sense amps 1008 and input/output buffer 1012, and output data is received from memory array 1002 via signal output lines from sense amps 1008 to input/output buffer 1012. Input data can be received from the host apparatus, and output data can be delivered to the host apparatus via the I/O bus.

Commands received from the host apparatus can be provided to a command interface 1016. Command interface 1016 can be configured to receive external control signals from the host apparatus and determine whether data input to the input/output buffer 1012 is write data, a command, or an address. Input commands can be transferred to a state machine 1020.

State machine 1020 can be configured to manage programming and reprogramming of memory array 1002 (as well as other memory banks of a multi-bank memory array). Instructions provided to state machine 1020 are implemented according to control logic configurations, enabling state machine 1020 to manage read, write, erase, data input, data output, and other functionality associated with memory cell array 1002. In some aspects, state machine 1020 can send and receive acknowledgments and negative acknowledgments regarding successful receipt or execution of various commands. In further embodiments, state machine 1020 can decode and implement status-related commands, decode and implement configuration commands, and so on.

To implement read, write, erase, input, output, etc., functionality, state machine 1020 can control clock source(s) 1010 or reference and control signal generator(s) 1018. Control of clock source(s) 1010 can cause output pulses configured to facilitate row controller 1004 and column controller 1006 implementing the particular functionality. Output pulses can be transferred to selected bit lines by column controller 1006, for instance, or word lines by row controller 1004, for instance.

In connection with FIG. 11, the systems, devices, and/or processes described herein can be embodied within hardware, such as a single integrated circuit (IC) chip, multiple ICs, an application specific integrated circuit (ASIC), or the like. Further, the order in which some or all of the process blocks appear in each process should not be deemed limiting. Rather, it should be understood that some of the process blocks can be executed in a variety of orders, not all of which may be explicitly illustrated herein.

With reference to FIG. 11, a suitable environment 1100 for implementing various aspects of the claimed subject matter includes a computer 1102. The computer 1102 includes a processing unit 1104, a system memory 1110, a codec 1114, and a system bus 1108. The system bus 1108 couples system components including, but not limited to, the system memory 1110 to the processing unit 1104. The processing unit 1104 can be any of various available processors. Dual microprocessors and other multiprocessor architectures also can be employed as the processing unit 1104.

The system bus 1108 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 1394), and Small Computer Systems Interface (SCSI).

The system memory 1110 includes volatile memory 1110A and non-volatile memory 1110B. The basic input/output system (BIOS), containing the basic routines to transfer information between elements within the computer 1102, such as during start-up, is stored in non-volatile memory 1110B. In addition, according to present innovations, codec 1114 may include at least one of an encoder or decoder, wherein the at least one of an encoder or decoder may consist of hardware, software, or a combination of hardware and software. Although, codec 1114 is depicted as a separate component, codec 1114 may be contained within non-volatile memory 1110B. By way of illustration, and not limitation, non-volatile memory 1110B can include read only memory (ROM), programmable ROM (PROM), electrically programmable ROM (EPROM), electrically erasable programmable ROM (EEPROM), or flash memory, two-terminal memory, and so on. Volatile memory 1110A includes random access memory (RAM), and in some embodiments can embody a cache memory. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM).

Computer 1102 may also include removable/non-removable, volatile/non-volatile computer storage medium. FIG. 11 illustrates, for example, disk storage 1106. Disk storage 1106 includes, but is not limited to, devices like a magnetic disk drive, solid state disk (SSD) floppy disk drive, tape drive, Jaz drive, Zip drive, LS-100 drive, flash memory card, or memory stick. In addition, disk storage 1106 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 1106 to the system bus 1108, a removable or non-removable interface is typically used, such as storage interface 1112. It is appreciated that storage devices 1106 can store information related to a user. Such information might be stored at or provided to a server or to an application running on a user device. In one embodiment, the user can be notified (e.g., by way of output device(s) 1132) of the types of information that are stored to disk storage 1106 or transmitted to the server or application. The user can be provided the opportunity to opt-in Or opt-out of having such information collected and/or shared with the server or application (e.g., by way of input from input device(s) 1142).

It is to be appreciated that FIG. 11 describes software that acts as an intermediary between users and the basic computer resources described in the suitable operating environment 1100. Such software includes an operating system 1106A. Operating system 1106A, which can be stored on disk storage 1106, acts to control and allocate resources of the computer system 1102. Applications 1106C take advantage of the management of resources by operating system 1106A through program modules 1106D, and program data 1106D, such as the boot/shutdown transaction table and the like, stored either in system memory 1110 or on disk storage 1106. It is to be appreciated that the claimed subject matter can be implemented with various operating systems or combinations of operating systems.

A user enters commands or information into the computer 1102 through input device(s) 1142. Input devices 1142 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 1104 through the system bus 1108 via input port(s) 1140. Input port(s) 1140 include, for example, a serial port, a parallel port, a game port, and a universal serial bus (USB). Output device(s) 1132 use some of the same type of ports as input device(s) 1142. Thus, for example, a USB port may be used to provide input to computer 1102 and to output information from computer 1102 to an output device 1132. Output adapter 1130 is provided to illustrate that there are some output devices 1132 like monitors, speakers, and printers, among other output devices 1132, which require special adapters. The output adapters 1130 include, by way of illustration and not limitation, video and sound cards that provide a means of connection between the output device 1132 and the system bus 1108. It should be noted that other devices and/or systems of devices provide both input and output capabilities such as remote computer(s) 1138.

Computer 1102 can operate in a networked environment using logical connections to one or more remote computers, such as remote computer(s) 1124. The remote computer(s) 1124 can be a personal computer, a server, a router, a network PC, a workstation, a microprocessor based appliance, a peer device, a smart phone, a tablet, or other network node, and typically includes many of the elements described relative to computer 1102. For purposes of brevity, only a memory storage device 1126 is illustrated with remote computer(s) 1124. Remote computer(s) 1124 is logically connected to computer 1102 through a network 1122 and then connected via communication interface(s) 1120. Network 1122 encompasses wire or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication interface(s) 1120 refers to the hardware/software employed to connect the network 1122 to the bus 1108. While communication interface(s) 1120 is shown for illustrative clarity inside computer 1102, it can also be external to computer 1102. The hardware/software necessary for connection to the network 1122 includes, for exemplary purposes only, internal and external technologies such as, modems including regular telephone grade modems, cable modems and DSL modems, ISDN adapters, and wired and wireless Ethernet cards, hubs, and routers.

The illustrated aspects of the disclosure may also be practiced in distributed computing environments where certain tasks are performed by remote processing devices that are linked through a communications network. In a distributed computing environment, program modules or stored information, instructions, or the like can be located in local or remote memory storage devices.

Moreover, it is to be appreciated that various components described herein can include electrical circuit(s) that can include components and circuitry elements of suitable value in order to implement the embodiments of the subject disclosure. Furthermore, it can be appreciated that many of the various components can be implemented on one or more IC chips. For example, in one embodiment, a set of components can be implemented in a single IC chip. In other embodiments, one or more of respective components are fabricated or implemented on separate IC chips.

In regard to the various functions performed by the above described components, architectures, circuits, processes and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the embodiments. In this regard, it will also be recognized that the embodiments include a system as well as a computer-readable medium having computer-executable instructions for performing the acts and/or events of the various processes.

In addition, while a particular feature may have been disclosed with respect to only one of several implementations, such feature may be combined with one or more other features of the other implementations as may be desired and advantageous for any given or particular application. Furthermore, to the extent that the terms “includes,” and “including” and variants thereof are used in either the detailed description or the claims, these terms are intended to be inclusive in a manner similar to the term “comprising”.

As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Further embodiments can be envisioned to one of ordinary skill in the art after reading this disclosure. For example, in various embodiments, a circuit illustrated in one disclosed Figure can be operably coupled to a circuit illustrated in another disclosed Figure, where suitable; a portion of a circuit illustrated in one disclosed Figure can be operably coupled to a circuit or portion thereof illustrated in another disclosed Figure, where suitable; and circuits or devices known in the art or reasonably conveyed to one of ordinary skill in the art by way of the context provided herein can be operably coupled to circuits or portions of circuits disclosed in the subject disclosure, where suitable.

In other embodiments, combinations or sub-combinations of the above disclosed embodiments can be advantageously made. The block diagrams of the architecture and flow charts are grouped for ease of understanding. However, it should be understood that combinations of blocks, additions of new blocks, re-arrangement of blocks, and the like are contemplated in alternative embodiments of the present disclosure. It is also understood that the examples and embodiments described herein are for illustrative purposes only and that various modifications or changes in light thereof will be suggested to persons skilled in the art and are to be included within the spirit and purview of this application and scope of the appended claims.

What is Claimed is:

1. A solid state logic system, comprising:
a plurality of bit lines comprising a bit line, and a plurality of wordlines comprising a first wordline and a second wordline;
a first memory circuit at an intersection of the bit line and the first wordline and comprising a first non-volatile resistive switching cell; and
a second memory circuit at a second intersection of the bit line and the second wordline and comprising a second non-volatile resistive switching cell, wherein respective data values corresponding to a first data matrix are stored at the first non-volatile resistive switching cell and at the second non-volatile resistive switching cell, and wherein a second data matrix is received onto the plurality of wordlines and is provided to the solid state logic system as a system input, and wherein:
in response to receiving the second data matrix on the plurality of wordlines and storing of the first data matrix at the resistive switching memory cells, the first memory circuit and the second memory circuit generate an output on the plurality of bit lines, and
the first memory circuit further comprises a transistor device having a channel region and a control gate, wherein the transistor device is directly or indirectly responsive to a value stored at the first non-volatile resistive switching cell, and wherein the channel region is associated with a plurality of conductance values respectively corresponding to different voltage magnitudes applied to the control gate.

2. The solid state logic system of claim 1, wherein the plurality of conductance values includes a number x of conductance values having conductance magnitudes: Cx, where x is greater than one, and whose conductance magnitudes are characterized by a relationship: Cx=C₀*Nₓ where C₀ is a smallest conductance magnitude of the plurality of conductance values and N is a radix of a numbering system represented by a number of states of the first non-volatile resistive switching cell.

3. The solid state logic system of claim 2, further comprising a voltage controller for selecting the voltage magnitudes applied to the control gate, wherein N=2 representing a binary numbering system, and the voltage controller is configured to select values of the voltage magnitudes that cause the channel region to have the conductance magnitudes characterized by the relationship: Cx=C₀*2^{x}.

4. The solid state logic system of claim 1, wherein the first memory circuit further comprises a second transistor device and an inverter, and further wherein:
the second transistor device comprises a gate node coupled to the first wordline, a source node connected to a first terminal of the first non-volatile resistive switching cell and a drain node coupled to an input of the inverter;
the inverter has an output coupled to the control gate of the transistor device of the first memory circuit, and
a second terminal of the first non-volatile resistive switching cell is coupled to a low voltage or ground.

5. The solid state logic system of claim 4, wherein in response to a data value of the second data matrix connected to the first wordline being high and in response to a first data value of the respective data values of the first data matrix stored by the first non-volatile resistive switching cell being high, the input to the inverter is brought to a low state and a reference voltage selected to one of the different voltage magnitudes is applied from the output of the inverter to the control gate.

6. The solid state logic system of claim 5, wherein the channel region of the transistor device has a conductance value of the plurality of conductance values corresponding to the one of the different voltage magnitudes applied to the control gate.

7. The solid state logic system of claim 4, wherein in response to a data value of the second data matrix connected to the first wordline being low, or in response to a first data value of the respective data values of the first data matrix stored by the first non-volatile resistive switching cell being low, the input to the inverter remains in a high state and the output of the inverter and the control gate of the transistor device retains a low state.

8. The solid state logic system of claim 7, wherein the channel region of the transistor device has a conductance value of zero or substantially zero in response to the control gate of the transistor device retaining the low state.

9. The solid state logic system of claim 1, further comprising:
a second bit line of the plurality of bit lines;
a third memory circuit at a third intersection of the second bit line and the first wordline; and
a fourth memory circuit at a fourth intersection of the second bit line and the second wordline, wherein the respective data values of the first data matrix are multi-bit data values comprising a first multi-bit data value and a second multi-bit data value.

10. The solid state logic system of claim 9, wherein a zeroth order bit of the first multi-bit data value is stored at the first memory circuit, a first order bit of the first multi-bit data value is stored at the third memory circuit, a zeroth order bit of the second multi-bit data value is stored at the second memory circuit, and a first order bit of the second multi-bit data value is stored at the fourth memory circuit.

11. The solid state logic system of claim 10, further comprising a signal amplifier connected to the second bit line and configured to amplify an output of the third memory circuit and the fourth memory circuit on the second bit line in proportion to a ratio of zeroth order bits to first order bits in a numbering system embodied by the multi-bit data values of the first data matrix.

12. The solid state logic system of claim 11, further comprising a summing circuit coupled to the plurality of bit lines and that receives an output generated by the first bit line, and receives an amplified output generated by the signal amplifier connected to the second bit line, and sums the output and the amplified output to generate a response of the solid state logic system to the system input of the second data matrix.

13. A method, comprising:
programming a first resistive memory circuit with a first data value of a first data matrix;
programming a second resistive memory circuit with a second data value of the first data matrix;
inputting data values of a second data matrix onto a plurality of wordlines coupled to the first resistive memory circuit or to the second resistive memory circuit;
sensing a bit line connected to the first resistive memory circuit and to the second resistive memory circuit for a response of a solid state logic device to the inputting of the data values of the second data matrix onto the plurality of wordlines, wherein the solid state logic device comprises the first resistive memory circuit, the second resistive memory circuit, the bit line and the plurality of wordlines; and
generating an output representing the response of the solid state logic device in response to sensing the bit line, wherein the first resistive memory circuit comprises a non-volatile two-terminal resistive switching memory cell for storing the first data value and a transistor device directly or indirectly responsive to the first data value stored at the non-volatile two-terminal resistive switching memory cell for generating a portion of the output on the bit line.

14. The method of claim 13, wherein:
the first resistive memory circuit further comprises a second transistor device directly or indirectly responsive to the first data value stored at the non-volatile two-terminal resistive switching memory cell for generating a second portion of the output on the bit line,
a data value of the second data matrix is a multi-bit data value comprising a first order bit, and comprising a second order bit that is equal to a product of the first order bit and a multiplier, the method further comprising:
entering the first order bit of the data value of the second data matrix onto a wordline of the plurality of wordlines coupled to the first resistive memory circuit; and
entering the second order bit of the data value of the second data matrix onto a second wordline of the plurality of wordlines coupled to the first resistive memory circuit, and further wherein:
the transistor device is responsive to a value of the first order bit of the data value and to the first data value stored at the non-volatile two-terminal resistive switching memory cell to selectively produce a first current on the bit line, and
the second transistor device is responsive to a second value of the second order bit and to the first data value stored at the non-volatile two-terminal resistive switching memory cell to selectively produce a second current on the bit line.

15. The method of claim 14, wherein the second current on the bit line produced by the second transistor device is equal to or approximately equal to a product of the first current on the bit line produced by the first transistor device and the multiplier.

16. The method of claim 15, wherein the multi-bit data value of the second data matrix is a positional notation number comprising the first order bit and the second order bit and wherein the multiplier is a base of the positional notation number.

17. The method of claim 16, wherein the positional notation number is a binary number and the multiplier is two.

18. The method of claim 13, further comprising at least one of:
sensing a first magnitude on the bit line provided by the portion of the output on the bit line in response to the first data value having a first binary state; or sensing a second magnitude on the bit line provided by the portion of the output on the bit line in response to the first data value having a second binary state.

19. The method of claim 14, further comprising:
applying a reference voltage to the first memory circuit, wherein the reference voltage is transferred to a control gate of the transistor device in response to the first data value causing the non-volatile two-terminal resistive switching memory cell to have a low resistance state and in response to a value of the first order bit entered onto the wordline; and
applying a second reference voltage to the first memory circuit, wherein the second reference voltage is transferred to a control gate of the second transistor device in response to the first data value causing the non-volatile two-terminal resistive switching memory cell to have the low resistance state and in response to a second value of the second order bit entered onto the second wordline.

20. The method of claim 19, wherein a magnitude of the second reference voltage is different from a magnitude of the first reference voltage, and wherein the magnitude of the second reference voltage and the magnitude of the first reference voltage are selected to cause the second transistor device to have a channel conductance approximately twice the channel conductance of the transistor device.
